(19) United States
(12) Patent Application Publication
(10) Pub. No.: US 2023/0061355 A1
(43) Pub. Date: Mar. 2, 2023

(54) DISPLAY APPARATUS AND METHOD OF MANUFACTURING THE SAME

(71) Applicant: Samsung Display Co., Ltd., Yongin-si (KR)

(72) Inventors: Swaehyun Kim, Yongin-si (KR); Jeongho Lee, Yongin-si (KR); Youhan Moon, Yongin-si (KR)

(21) Appl. No.: 17/874,141

(22) Filed: Jul. 26, 2022

(30) Foreign Application Priority Data
Aug. 31, 2021 (KR) 10-2021-0115700

(51) Int. Cl. H01L 51/52; H01L 27/32; H01L 51/56

(52) U.S. Cl. CPC H01L 51/5253; H01L 27/3258; H01L 51/56; H01L 2227/323

(57) ABSTRACT

A display apparatus includes: a substrate comprising an opening area, a display area surrounding at least a portion of the opening area, and an intermediate area between the opening area and the display area; an organic insulating layer in the display area; a display element on the organic insulating layer and comprising a pixel electrode, an opposite electrode on the pixel electrode, and an intermediate layer between the pixel electrode and the opposite electrode; and a partition layer in the intermediate area and comprising a first partition and a second partition, wherein the intermediate layer comprises an organic layer extending toward the intermediate area from the display area, and the organic layer is separated by a plurality of first openings in an area between the organic insulating layer and the first partition and by a plurality of second openings in an area between the first partition and the second partition.

### CROSS-REFERENCE TO RELATED APPLICATION

The present application claims priority to and the benefit of Korean Patent Application No. 10-2021-0115700, filed on Aug. 31, 2021, in the Korean Intellectual Property Office, the entire disclosure of which is incorporated herein by reference.

### BACKGROUND

### 1. Field

Aspects of some embodiments of the present disclosure relate to a display apparatus and a method of manufacturing the same.

### 2. Description of the Related Art

Recently, display apparatuses have been used in various fields. Also, because of the decrease in the thickness and weight of display apparatuses, the range of uses of display apparatuses has widened.

An increase in the areas occupied by display areas in display apparatuses may enable the addition of functions added to or associated with the display apparatuses. To add various functions while increasing the display areas, research has been conducted into display apparatuses in which various components may be added to or within the display areas.

The above information disclosed in this Background section is only for enhancement of understanding of the background and therefore the information discussed in this Background section does not necessarily constitute prior art.

### SUMMARY

Aspects of some embodiments of the present disclosure relate to a display apparatus and a method of manufacturing the same, and for example, to a display apparatus having improved reliability and a method of manufacturing the same.

Aspects of some embodiments of the present disclosure include a display apparatus having relatively improved reliability and having an area where various components may be arranged, and a method of manufacturing the display apparatus. However, this is merely an example, and embodiments according to the present disclosure are not limited thereto.

Additional aspects will be set forth in part in the description which follows and, in part, will be apparent from the description, or may be learned by practice of the presented embodiments of the disclosure.

According to some embodiments of the present disclosure, a display apparatus includes a substrate including an opening area, a display area surrounding at least a portion of the opening area, and an intermediate area between the opening area and the display area, an organic insulating layer in the display area, a display element on the organic insulating layer and including a pixel electrode, an opposite electrode on the pixel electrode, and an intermediate layer between the pixel electrode and the opposite electrode, and a partition layer in the intermediate area and including a first partition and a second partition, wherein the intermediate layer further includes an organic layer extending towards the intermediate area from the display area, and the organic layer is separated by first openings in an area between the organic insulating layer and the first partition and by second openings in an area between the first partition and the second partition.

According to some embodiments, the display apparatus may further include a thin film transistor arranged in the display area and including a semiconductor layer and a gate electrode overlapping at least a portion of the semiconductor layer, a first interlayer insulating layer arranged on the thin film transistor, and a second interlayer insulating layer arranged on the first interlayer insulating layer, wherein the second interlayer insulating layer may further include a second inorganic layer extending towards the intermediate area from the display area, and the second inorganic layer may include a plurality of first through holes overlapping the plurality of first openings and the plurality of second openings.

According to some embodiments, the first interlayer insulating layer may include a first inorganic layer extending towards the intermediate area from the display area, and the first inorganic layer may include a plurality of second through holes overlapping the plurality of first openings and the plurality of second openings.

According to some embodiments, the display apparatus may further include a stopper layer arranged under the organic layer and in contact with the organic layer and including a plurality of third through holes corresponding to the plurality of first openings and the plurality of second openings.

According to some embodiments, the organic layer may be separated by a plurality of third openings in an area between the second partition and the opening area, and a width of each of the plurality of third openings may be the same as a width of each of the plurality of first openings.

According to some embodiments, the plurality of first openings may include at least two openings having a closed-loop shape, the at least two openings having the same center and different diameters.

According to some embodiments, the plurality of second openings may include at least two openings having a closed-loop shape, the at least two openings having the same center and different diameters.

According to some embodiments, the opposite electrode may extend towards the intermediate area from the display area and may include an electrode opening in the intermediate area, and an edge portion of the opposite electrode, which defines an outline of the electrode opening, may be in an area between the organic insulating layer and the first partition.

According to some embodiments, the display apparatus may further include an encapsulation layer arranged on the display element and including at least one inorganic encapsulation layer and an organic encapsulation layer, wherein the edge portion of the opposite electrode may overlap the organic encapsulation layer.

According to some embodiments of the present disclosure, a method of manufacturing a display apparatus, including preparing a substrate including an opening area, a display area surrounding at least a portion of the opening area, and an intermediate area between the opening area and the display area, forming a pixel circuit in the display area, forming a sacrificial layer in the intermediate area, forming an organic insulating layer on an upper portion of the pixel circuit, forming, in the intermediate area, a partition layer including a first partition and a second partition, sequentially forming, on the organic insulating layer, a pixel electrode electrically connected to the pixel circuit, an intermediate layer, and an opposite electrode, irradiating laser onto an organic layer on which the intermediate layer extends from the display area towards the intermediate layer, and forming, on the opposite electrode, an encapsulation layer including at least one inorganic encapsulation layer and an organic encapsulation layer, wherein the forming of the sacrificial layer includes forming a plurality of first lines in an area between the organic insulating layer and the first partition and forming a plurality of second lines in an area between the first partition and the second partition.

According to some embodiments, the method may further include forming a stopper layer in the intermediate area before the forming of the organic insulating layer.

According to some embodiments, the forming of the pixel circuit may include forming at least one metal layer in the display area, and forming at least one inorganic insulating layer on the at least one metal layer, wherein the sacrificial layer may include a same material as the at least one metal layer.

According to some embodiments, the inorganic insulating layer may further include an inorganic layer extending towards the intermediate area from the display area, and the irradiating of the laser may include removing together the organic layer and the inorganic layer arranged on the sacrificial layer by removing the sacrificial layer through laser irradiation.

According to some embodiments, as the sacrificial layer, and the organic layer and the inorganic layer, which are arranged on the sacrificial layer, are removed together, the organic layer may be separated by a plurality of first openings in an area between the organic insulating layer and the first partition and by a plurality of second openings in an area between the first partition and the second partition.

According to some embodiments, the forming of the sacrificial layer may further include forming a plurality of third lines in an area between the second partition and the opening area.

According to some embodiments, a width of each of the plurality of third lines may be the same as a width of each of the plurality of first lines.

According to some embodiments, the inorganic insulating layer may further include an inorganic layer extending from the display area towards the intermediate area, and as the sacrificial layer, and the organic layer and the inorganic layer, which are arranged on the sacrificial layer, are removed together, the organic layer may be separated by a plurality of third openings in an area between the second partition and the opening area.

According to some embodiments, in the irradiating of the laser, an electrode opening may be formed by removing a portion of the opposite electrode through laser irradiation.

According to some embodiments, an edge portion of the opposite electrode, which defines an outline of the electrode opening, may overlap the organic encapsulation layer.

According to some embodiments, a width of each of the plurality of first lines and the plurality of second lines may be less than a diameter of a laser beam.

Other aspects, features, and characteristics other than those described above will become more apparent from the following detailed description, claims and drawings for carrying out the disclosure.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a schematic perspective view of a display apparatus according to some embodiments;

FIG. 2 is a schematic cross-sectional view of a display panel according to some embodiments, taken along the line I-I′ of FIG. 1;

FIG. 3 is a schematic plan view of a display panel according to some embodiments;

FIG. 4 illustrates an equivalent circuit connected to any one of light-emitting diodes of a display panel according to some embodiments;

FIG. 5 is a plan view of a portion of a display panel according to some embodiments;

FIG. 6 is a schematic cross-sectional view of a display panel according to some embodiments, taken along the line VI-VI′ of FIG. 5;

FIGS. 7A to 7D are cross-sectional view of an enlarged portion VII of FIG. 6 according to some embodiments;

FIG. 8 is a plan view illustrating an extract of at least one organic layer of FIG. 6 according to some embodiments;

FIG. 9 is a plan view illustrating an extract of an opposite electrode of FIG. 6 according to some embodiments;

FIGS. 10A to 10D are cross-sectional views of a method of manufacturing a display panel, according to some embodiments;

FIG. 11A is an enlarged cross-sectional view of a portion VIII of FIG. 10A; and FIG. 11B is a plan view of portion VIII of FIG. 10A according to some embodiments.

### DETAILED DESCRIPTION

Reference will now be made in more detail to aspects of some embodiments, which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, aspects of some embodiments will be illustrated in the drawings and described in more detail in the written description. The attached drawings for illustrating aspects of some embodiments of the present disclosure are referred to in order to gain a sufficient understanding of the present disclosure, the merits thereof, and the objectives accomplished by the implementation of the present disclosure. The disclosure may, however, be embodied in many different forms and should not be construed as being limited to the embodiments set forth herein.

Hereinafter, aspects of some embodiments of the present invention will be described in more detail with reference to the attached drawings. Like reference numerals in the drawings denote like elements, and thus their description will be omitted.

It will be understood that although the terms “first,” “second,” etc. may be used herein to describe various components, these components should not be limited by these terms. These components are only used to distinguish one component from another.

As used herein, the singular forms “a,” “an,” and “the” are intended to include the plural forms as well, unless the context clearly indicates otherwise.

It will be further understood that the terms comprises and/or comprising used herein specify the presence of stated features or components, but do not preclude the presence or addition of one or more other features or components.

It will be understood that when a layer, region, or component is referred to as being “formed on” another layer, region, or component, it can be directly or indirectly formed on the other layer, region, or component. That is, for example, intervening layers, regions, or components may be present.

It will be understood that when a layer, region, or component is referred to as being connected to another layer, region, or component, it can be directly and/or indirectly connected to the other layer, region, or component. That is, for example, intervening layers, regions, or components may be present. It will be understood that when a layer, region, or component is referred to as being electrically connected to another layer, region, or component, it can be electrically and directly and/or indirectly connected to the other layer, region, or component. That is, for example, intervening layers, regions, or components may be present.

In the present embodiments, an expression such as “A and/or B” indicates A, B, or A and B. Also, an expression such as “at least one of A and B” indicates A, B, or A and B.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When certain embodiments may be implemented differently, a specific process order may be performed differently from the described order. For example, two consecutively described processes may be performed substantially at the same time or performed in an order opposite to the described order.

Sizes of components in the drawings may be exaggerated for convenience of explanation. In other words, since sizes and thicknesses of components in the drawings are arbitrarily illustrated for convenience of explanation, the following embodiments are not limited thereto.

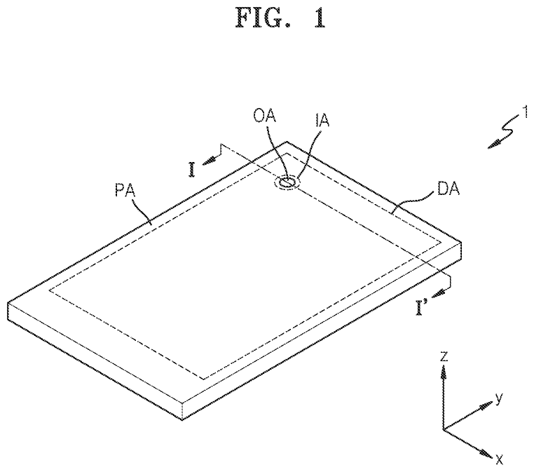

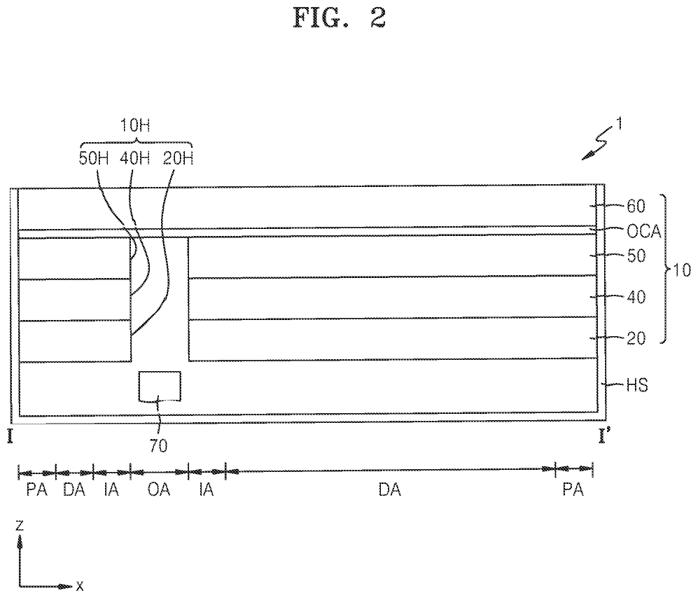

FIG. 1 is a schematic perspective view of a display apparatus according to some embodiments.

Referring to FIG. 1, a display apparatus 1 displays a moving image (e.g., video) or a still image (e.g., a static image) and may be used as a display screen of various products, for example, a portable electronic device such as a mobile phone, a smartphone, a tablet Personal Computer (PC), a mobile communication terminal, a personal digital assistant, an e-book terminal, a Portable Multimedia Player (PMP), a navigation device, or an Ultra Mobile PC (UMPC), a television (TV), a laptop, a monitor, a billboard, an Internet of Things (IoT) device, and the like. Also, the display apparatus 1 according to some embodiments may be used in a wearable device such as a smartwatch, a watch phone, an eyewear display, or a head mounted display (HMD). Also, the display apparatus 1 may be used as a display in an instrument cluster of a vehicle, a Center Information Display (CID) mounted on a center fascia or a dashboard of a vehicle, a room mirror display replacing a side-view mirror of a vehicle, or a car headrest monitor provided for rear-seat entertainment. For convenience of explanation, FIG. 1 illustrates that the display apparatus 1 is used as a smart phone.

The display apparatus 1 has a rectangular shape on a plane (e.g., in a plan view, or a view perpendicular or normal with respect to a plane parallel to a display surface of the display apparatus 1, for example, when viewed from the z-direction). For example, as illustrated in FIG. 1, the shape of the display apparatus 1 may be a rectangle having short sides in an x direction and long sides in a y direction. An edge, on which the short side in the x direction meets the long side in the y direction, may be rounded to have a certain curvature or may have a right angle. A planar shape of the display apparatus 1 is not limited to a rectangle and may be, for example, another polygon, an oval, or an atypical shape.

The display apparatus 1 may include an opening area OA and a display area DA that at least partially surrounds the opening area OA. The display apparatus 1 may include an intermediate area IA, which is between the opening area OA and the display area DA, and a peripheral area PA, which surrounds an outer side of the display area DA, for example, the display area DA.

The opening area OA may be located on an inner side of the display area DA. According to some embodiments, as illustrated in FIG. 1, the opening area OA may be located on an upper left side of the display area DA. Alternatively, the opening area OA may be variously located. For example, the opening area OA may be located on the center of the display area DA or on an upper right side of the display area DA. On a plan view of the present specification, the terms “left,” “right,” “upper,” and “lower” denote directions in which the display apparatus 1 is vertically viewed. For example, the term “left” indicates a −x direction, the term “right” indicates a +x direction, the term “upper” indicates a +y direction, and the term “lower” indicates a −y direction. FIG. 1 illustrates one opening area OA, but according to some embodiments, there may be a plurality of opening areas OA.

FIG. 2 is a schematic cross-sectional view of a display panel according to some embodiments, taken along a line I-I′ of FIG. 1.

Referring to FIG. 2, the display apparatus 1 may include a display panel 10 and a component 70 arranged in the opening area OA of the display panel 10. The display panel 10 and the component 70 may be accommodated in a housing HS.

The display panel 10 may include a display element layer 20, an input detection layer 40, an optical functional layer 50, and a cover window 60.

The display element layer 20 may include a display element (or an emission element) that emits light to display an image. The display element may include a light-emitting diode, for example, an organic light-emitting diode including an organic emission layer.

The input detection layer 40 may obtain coordinate information according to an external input, for example, a touch event. The input detection layer 40 may include a sensing electrode (or a touch electrode) and trace lines connected to the sensing electrode. The input detection layer 40 may be arranged on the display element layer 20. The input detection layer 40 may detect an external input in a mutual cap manner and/or a self-cap manner.

The input detection layer 40 may be directly formed on the display element layer 20 or separately formed, and then may be coupled to the display element layer 20 by an adhesive layer such as an optical clear adhesive (OCA). For example, the input detection layer 40 may be continuously formed after a process of forming the display element layer 20, and in this case, the adhesive layer may not be located between the input detection layer 40 and the display element layer 20. FIG. 2 illustrates that the input detection layer 40 is arranged between the display element layer 20 and the optical functional layer 50, but according to some embodiments, the input detection layer 40 may be arranged on the optical functional layer 50.

The optical functional layer 50 may include a reflection prevention layer. The reflection prevention layer may decrease the reflectivity of light (external light) that is incident to the display panel 10 from the outside through the cover window 60. The reflection prevention layer may include a retarder and a polarizer. The retarder may be of a film type or a liquid-crystal coating type. The polarizer may also be of a film type or a liquid-crystal coating type. A polarizer of a film type may include a stretched synthetic resin film, and a polarizer of a liquid-crystal coating type may include liquid crystals arranged in a certain array.

According to some embodiments, the reflection prevention layer may include a black matrix and structures of color filters. The color filters may be arranged by considering colors of light respectively emitted from the light-emitting diodes of the display element layer 20. According to some embodiments, the reflection prevention layer may include a destructive interference structure. The destructive interference structure may include a first reflection layer and a second reflection layer arranged on different layers. First reflection light and second reflection light, which are respectively reflected from the first reflection layer and the second reflection layer, may destructively interfere with each other, and the reflectivity of external light may decrease accordingly.

The optical functional layer 50 may include a lens layer. The lens layer may improve the output efficiency of the light emitted from the display element layer 20 or may decrease a difference of chromaticity. The lens layer may include a layer having a convex or concave lens shape and/or may include layers of which refractive indices are different. The optical functional layer 50 may include both the reflection prevention layer and the lens layer or may include any one thereof.

The display panel 10 may include an opening 10H. FIG. 2 illustrates that the display element layer 20, the input detection layer 40, and the optical functional layer 50 respectively include first, second, and third openings 20H, 40H, and 50H and the first, second, and third openings 20H, 40H, and 50H overlap each other.

The first opening 20H may penetrate a bottom surface of the display element layer 20 from an upper surface thereof, the second opening 40H may penetrate a bottom surface of the input detection layer 40 from an upper surface thereof, and the third opening 50H may penetrate a bottom surface of the optical functional layer 50 from an upper surface thereof.

The opening 10H of the display penal 10, for example, the first, second, and third openings 20H, 40H, and 50H, may overlap each other in the opening area OA. Sizes (or diameters) of the first, second, and third openings 20H, 40H, and 50H may be the same as or different from each other.

According to some embodiments, at least one of the display element layer 20, the input detection layer 40, or the optical functional layer 50 may not include an opening. For example, any one component or two components selected from among the display element layer 20, the input detection layer 40, and the optical functional layer 50 may not include an opening.

The cover window 60 may be arranged on the optical functional layer 50. The cover window 60 may be coupled to the optical functional layer 50 by an adhesive layer such as an OCA arranged between the cover window 60 and the optical functional layer 50. The cover window 60 may include a glass material or a plastic material. The plastic material may include polyethersulfone, polyacrylate, polyether imide, polyethylene naphthalate, polyethylene terephthalate, polyphenylene sulfide, polyarylate, polyimide, polycarbonate, cellulose acetate propionate, or the like.

The cover window 60 may include a flexible window. For example, the cover window 60 may include a polyimide window or an ultra-thin glass window.

The opening area OA may be a component area (e.g., a sensor area, a camera area, a speaker area, etc.) where the component 70 for adding various functions to the display apparatus 1 may be arranged. The component 70 may overlap the opening 10H of the display panel 10.

The component 70 may include an electronic element. For example, the component 70 may be an electronic element using light or sound. For example, the electronic element may include a sensor, for example, an infrared sensor, which uses light, a camera that receives light and captures images, a sensor that measures a distance or recognizes fingerprints by outputting and detecting light or sound, a small lamp that outputs light, a speaker that outputs sound, or the like. The electronic element using light may use light in various wavelength bands such as visible light, infrared light, or ultraviolet light. The opening area OA may correspond to a transmission area where light and/or sound, which is output to the outside from the component 70 or travels from the outside to the electronic element, may pass.

According to some embodiments, when the display apparatus 1 is used as a smart watch or an instrument cluster of a vehicle, the component 70 may be a member including clock hands or needles indicating certain information (e.g., vehicle speed, etc.). In this case, unlike the illustration of FIG. 1, the cover window 60 may include an opening located in the opening area OA to make the component 70 such as a needle be exposed to the outside. Alternatively, when the display apparatus 1 includes the component 70 such as a speaker, the cover window 60 may include an opening corresponding to the opening area OA.

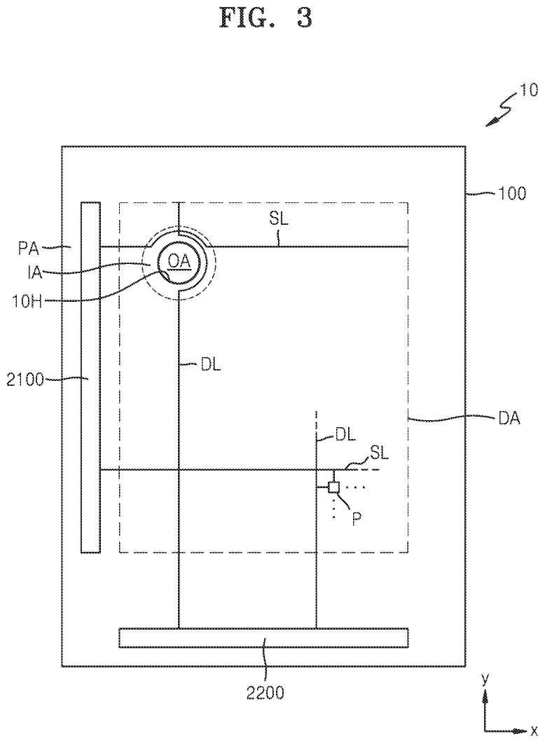

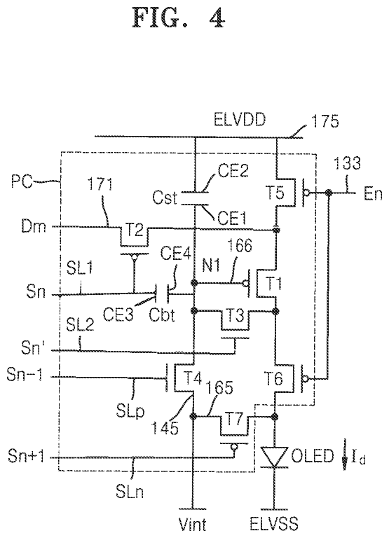

FIG. 3 is a schematic plan view of a display panel according to some embodiments, and FIG. 4 illustrates an equivalent circuit connected to any one of light-emitting diodes of a display panel.

Referring to FIG. 3, the display panel 10 may include the opening area OA, the display area DA, the intermediate area IA, and the peripheral area PA. The display panel 10 may include a plurality of pixels P arranged in the display area DA and may be configured to display images by using light, e.g., red light, green light, or blue light, which is emitted from a light-emitting diode of each pixel P.

The light-emitting diode of each pixel P may include the organic light-emitting diode OLED as illustrated in FIG. 4, and each organic light-emitting diode OLED may be electrically connected to a pixel circuit PC. FIG. 4 illustrates that the light-emitting diode includes the organic light-emitting diode OLED, but according to some embodiments, the display panel 10 may include the inorganic light-emitting diode described above, instead of the organic light-emitting diode OLED.

Referring to FIG. 4, the pixel circuit PC may include first to seventh transistors T1 to T7, a storage capacitor Cst, and a boost capacitor Cbt. In some embodiments, the pixel circuit PC may not include the boost capacitor Cbt, and hereinafter, the pixel circuit PC includes the boost capacitor Cbt for convenience of explanation.

Some of the first to seventh transistors T1 to T7 may each be an n-channel MOSFET (NMOS), and the others thereof may each be a p-channel MOSFET (PMOS). For example, the third and fourth transistors T3 and T4 may each be an NMOS, and the others of the first to seventh transistors T1 to T7 may each be a PMOS. According to some embodiments, the third, fourth, and seventh transistors T3, T4, and T7 may each be an NMOS, and the others of the first to seventh transistors T1 to T7 may each be a PMOS. Alternatively, only one of the first to seventh transistors T1 to T7 may be an NMOS, and the others of thereof may each be a PMOS.

The first to seventh transistors T1 to T7, the storage capacitor Cst, and the boost capacitor Cbt may be connected to the trace lines. The trace lines may include: a first scan line SL1 configured to transmit a first scan signal Sn; a second scan line SL2 configured to transmit a second scan signal Sn′; a previous scan line SLp configured to transmit a previous scan signal Sn−1; an emission control line 133 configured to transmit an emission control signal En; a next scan line SLn configured to transmit a next scan signal Sn+1; and a data line 171 crossing the first scan line SL1 and configured to transmit a data signal Dm.

A driving voltage line 175 may be configured to transmit a driving voltage ELVDD to the first transistor T1, and first and second initialization voltage lines 145 and 165 may be configured to transmit an initialization voltage Vint.

The first transistor T1 may be a driving transistor. A first gate electrode (or a first control electrode) of the first transistor T1 may be connected to the storage capacitor Cst, and a first electrode of the first transistor T1 may be electrically connected to the driving voltage line 175 via the fifth transistor T5, and a second electrode of the first transistor T1 may be electrically connected to a pixel electrode of the organic light-emitting diode OLED via the sixth transistor T6. One of the first and second electrodes of the first transistor T1 may be a source electrode, and the other thereof may be a drain electrode. The first transistor T1 may be configured to provide a driving current Id to the organic light-emitting diode OLED by receiving a data signal Dm according to a switching operation of the second transistor T2.

The second transistor T2 may be a switching transistor. A second gate electrode (or a second control electrode) of the second transistor T2 may be connected to the first scan line SL1, a first electrode of the second transistor T2 may be connected to the data line 171, a second electrode of the second transistor T2 may be connected to the first electrode of the first transistor T1 and may be electrically connected to the driving voltage line 175 via the fifth transistor T5. One of the first and second electrodes of the second transistor T2 may be a source electrode, and the other thereof may be a drain electrode. The second transistor T2 may be turned on in response to the first scan signal Sn transmitted through the first scan line SL1 and may perform a switching operation in which the data signal Dm transmitted to the data line 171 is transmitted to the first electrode of the first transistor T1.

The third transistor T3 may be a compensation transistor that compensates for a threshold voltage of the first transistor T1. A third gate electrode (or a compensation control electrode) of the third transistor T3 is connected to the second scan line SL2. A first electrode of the third transistor T3 is connected to the first gate electrode of the first transistor T1 and a lower electrode CE1 of the storage capacitor Cst through a node connection line 166. The first electrode of the third transistor T3 may be connected to the fourth transistor T4. A second electrode of the third transistor T3 is connected to the second electrode of the first transistor T1 and electrically connected to the pixel electrode of the organic light-emitting diode OLED via the sixth transistor T6. One of the first and second electrodes of the third transistor T3 may be a source electrode, and the other thereof may be a drain electrode.

The third transistor T3 is turned on in response to the second scan signal Sn′ transmitted through the second scan line SL2 and diode-connects the first transistor T1 by electrically connecting the first gate electrode and the second electrode of the first transistor T1 to each other.

The fourth transistor T4 may be a first initialization transistor that initializes the first gate electrode of the first transistor T1. A fourth gate electrode (or a fourth control electrode) of the fourth transistor T4 is connected to the previous scan line SLp. A first electrode of the fourth transistor T4 is connected to the first initialization voltage line 145. A second electrode of the fourth transistor T4 may be connected to the lower electrode CE1 of the storage capacitor Cst, the first electrode of the third transistor T3, and the first gate electrode of the first transistor T1. One of the first and second electrodes of the fourth transistor T4 may be a source electrode, and the other thereof may be a drain electrode. The fourth transistor T4 may be turned on in response to the previous scan signal Sn−1 transmitted through the scan line SLp and perform an initialization operation of initializing a voltage of the first gate electrode of the first transistor T1 by transmitting the initialization voltage Vint to the first gate electrode of the first transistor T1.

The fifth transistor T5 may be an operation control transistor. A fifth gate electrode (or a fifth control electrode) of the fifth transistor T5 is connected to the emission control line 133, a first electrode of the fifth transistor T5 is connected to the driving voltage line 175, and a second electrode of the fifth transistor T5 is connected to the first electrode of the first transistor T1 and the second electrode of the second transistor T2. One of the first and second electrodes of the fifth transistor T5 may be a source electrode, and the other thereof may be a drain electrode.

The sixth transistor T6 may be an emission control transistor. A sixth gate electrode (or a sixth control electrode) of the sixth transistor T6 is connected to the emission control line 133, a first electrode of the sixth transistor T6 is connected to the second electrode of the first transistor T1 and the second electrode of the third transistor T3, and a second electrode of the sixth transistor T6 is connected to a second electrode of the seventh transistor T7 and the pixel electrode of the organic light-emitting diode OLED. One of the first and second electrodes of the sixth transistor T6 may be a source electrode, and the other thereof may be a drain electrode.

The fifth and sixth transistors T5 and T6 may be simultaneously turned on in response to the emission control signal En transmitted through the emission control line 133 and may allow the driving current Id to flow in the organic light-emitting diode OLED as the driving voltage ELVDD is transmitted to the organic light-emitting diode OLED.

The seventh transistor T7 may be a second initialization transistor that initializes the pixel electrode of the organic light-emitting diode OLED. A seventh gate electrode (or a seventh control electrode) of the seventh transistor T7 is connected to the next scan line SLn. A first electrode of the seventh transistor T7 is connected to the second initialization voltage line 165. A second electrode of the seventh transistor T7 is connected to the second electrode of the sixth transistor T6 and the pixel electrode of the organic light-emitting diode OLED. The seventh transistor T7 may be turned on in response to the next scan signal Sn+1 transmitted through the next scan line SLn and may initialize the pixel electrode of the organic light-emitting diode OLED. FIG. 4 illustrates that the seventh transistor T7 is connected to the next scan line SLn, but the seventh transistor T7 may be connected to the emission control line 133 and driven according to the emission control signal En.

The storage capacitor Cst includes the lower electrode CE1 and an upper electrode CE2. The lower electrode CE1 of the storage capacitor Cst is connected to the first gate electrode of the first transistor T1, and the upper electrode CE2 of the storage capacitor Cst is connected to the driving voltage line 175. The storage capacitor Cst may store electric charges corresponding to a difference between the voltage of the first gate electrode of the first transistor T1 and the driving voltage EVLDD.

The boost capacitor Cbt includes a third electrode CE3 and a fourth electrode CE4. The third electrode CE3 may be connected to the second gate electrode of the second transistor T2 and the first scan line SL1, and the fourth electrode CE4 may be connected to the first electrode of the third transistor T3 and the node connection line 166. When the first scan signal Sn transmitted to the first scan line SL1 is turned off, the boost capacitor Cbt may increase a voltage of a first node N1, and when the voltage of the first node N1 increases, a black gradation may be clearly represented.

The first node N1 may be an area where the first gate electrode of the first transistor T1, the first electrode of the third transistor T3, the second electrode of the fourth transistor T4, and the fourth electrode CE4 of the boost capacitor Cbt are connected.

According to some embodiments, FIG. 4 illustrates that the third and fourth transistors T3 and T4 are the NMOS, and the first, second, and fifth to seventh transistors T1, T2, and T5 to T7 are the PMOS. In the case of the first transistor T1 directly affecting the brightness of a display apparatus, the first transistor T1 is configured to include a semiconductor layer including polycrystalline silicon having high reliability, and thus, the display apparatus having a high resolution may be realized.

Referring back to FIG. 3, the intermediate area IA may surround the opening area OA. The intermediate area IA is an area where display elements such as organic light-emitting diodes for emitting light are not arranged, and trace lines, through which signals are transmitted to the pixels P around the opening area OA, may pass in the intermediate area IA. For example, as illustrated in FIG. 3, data lines DL and/or scan lines SL may cross the display area DA in the y direction and/or the x direction, and some of the data lines DL and/or the scan lines SL may bypass the intermediate area IA along the rim of the opening 10H of the display panel 10 formed in the opening area OA.

In the peripheral area PA, a scan driver 2100 configured to provide a scan signal to each pixel P, a data driver 2200 configured to provide a data signal to each pixel P, and a first main power line and a second main power line configured to provide a first power voltage EVLDD (of FIG. 4) and a second power voltage ELVSS (of FIG. 4) may be arranged. FIG. 3 illustrates that the data driver 2200 is arranged adjacent to one side of the substrate 100, but according to some embodiments, the data driver 2200 may be arranged on a printed circuit board electrically connected to a pad arranged on a side of the display panel 10. The printed circuit board may have flexibility, and a portion of the printed circuit board may be bent to be located under a rear surface of the substrate 100.

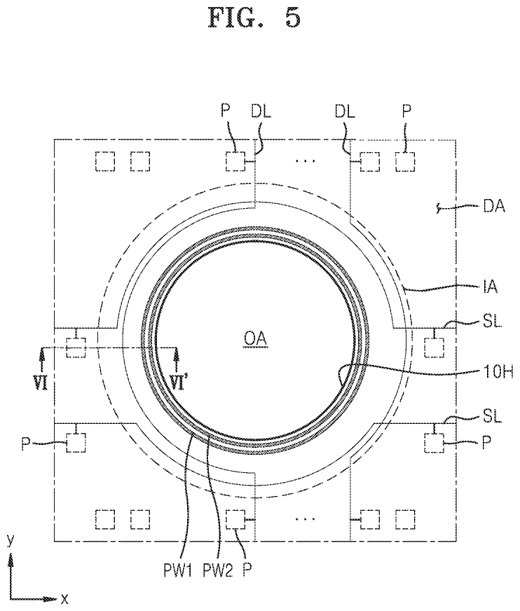

FIG. 5 is a plan view of a portion of a display panel according to some embodiments.

Referring to FIG. 5, the pixels P may be arranged in the display area DA, and the intermediate area IA may be between the opening area OA and the display area DA. For example, the intermediate area IA may surround or be in a periphery of the opening area OA. The pixels PX adjacent to the opening area OA may be spaced apart from each other with respect to the opening area OA on a plane (e.g., in a plan view). As illustrated in FIG. 5, in a plan view, the pixels PX may be vertically (e.g., in the y-direction) or horizontally (e.g., in the x-direction) spaced apart from each other with respect to the opening area OA. Each pixel P uses red, green, or blue light emitted from the light-emitting diode, and thus, locations of the pixels P illustrated in FIG. 5 correspond to locations of the light-emitting diodes, respectively. Therefore, the description that the pixels P are spaced apart from each other on a plane (e.g., in a plan view) with respect to the opening area OA may indicate that the light-emitting diodes are spaced apart from each other on a plane with respect to the opening area OA. For example, on a plane, the light-emitting diodes may be vertically or horizontally apart from each other with respect to the opening area OA.

Trace lines, which are adjacent to the opening area OA from among the trance lines configured to transmit signals to the pixel circuit connected to the light-emitting diode of each pixel P, may bypass the opening area OA and/or the opening 10H. Some of the data lines DL that pass the display area DA may extend in the ±y direction to provide data signals to the pixels P arranged on and under the data lines DL with the opening area OA therebetween, but may be bypassed along the edges of the opening area OA and/or the rim of the opening 10H in the intermediate area IA. Some of the scan lines SL that pass the display area DA may extend in the ±x direction to provide data signals to the pixels P arranged on the left and right sides of the scan lines SL with the opening area OA therebetween, but may be bypassed along the edges of the opening area OA and/or the rim of the opening 10H in the intermediate area IA.

FIG. 5 illustrates that the scan lines SL bypass the opening area OA and/or the opening 10H in the intermediate area IA, but one or more embodiments are not limited thereto. According to some embodiments, the scan lines SL may be separated or cut with respect to the opening area OA and/or the opening 10H, and the scan lines SL, which are arranged on a left side with respect to the opening area OA and/or the opening 10H, may receive signals from the scan driver 2100 arranged on a left side with respect to the display area DA, and the scan lines SL, which are arranged on a right side with respect to the opening area OA and/or the opening 10H, according to some embodiments, may receive signals from an additional scan driver arranged on the other side of the scan driver 2100 with respect to the display area DA.

At least one partition may be arranged in the intermediate area IA, wherein the at least one partition is arranged closer to the opening area OA than bypassing portions of the trace lines described above. FIG. 5 illustrates first and second partitions PW1 and PW2. Shapes of the first and second partitions PW1 and PW2 may each have a closed-loop surrounding the opening area OA and/or the opening 10H, and the first and second partitions PW1 and PW2 may be apart from each other in the intermediate area IA.

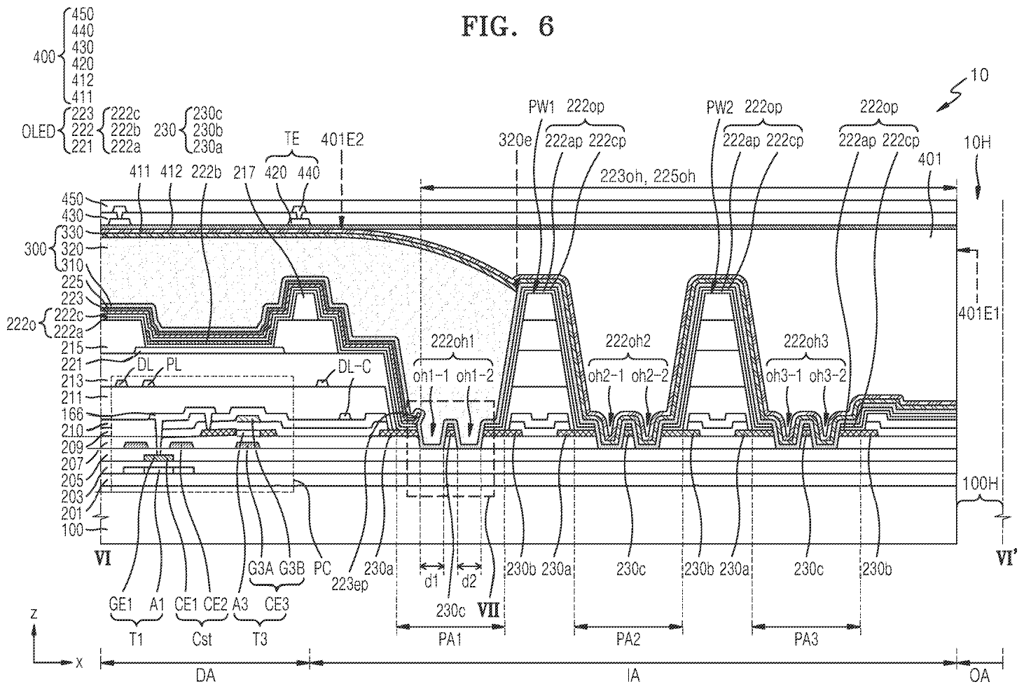

FIG. 6 is a schematic cross-sectional view of a display panel according to some embodiments, taken along a line VI-VI′ of FIG. 5.

FIG. 6 illustrates the display element layer 20 and the input detection layer 40 on the display element layer 20, and the optical functional layer 50 (of FIG. 2) and the cover window 60 (of FIG. 2) of the display panel 10 are omitted for convenience of explanation. The display element layer 20 includes the light-emitting diodes on the substrate 100 to correspond to the display area DA, and FIG. 6 illustrates one light-emitting diode, for example, the organic light-emitting diode OLED.

Referring to FIG. 6, the display panel 10 may include the opening 10H in the opening area OA. The opening 10H may be a through hole that passes through an upper surface and a lower surface of the display panel 10.

The description that the display panel 10 includes the opening 10H in the opening area OA may indicate that a plurality of layers included in the display panel 10 include an opening in the opening area OA. The substrate 100 may include an opening 100H in the opening area OA, and the opening 100H of the substrate 100 may be a through hole passing through upper and lower surfaces of the substrate 100.

Referring to the display area DA of FIG. 6, the pixel circuit PC may be arranged on the substrate 100, and the organic light-emitting diode OLED may be arranged on the pixel circuit PC.

The substrate 100 may include a glass material or polymer resin. For example, the polymer resin may include polyethersulfone, polyacrylate, polyether imide, polyethylene naphthalate, polyethylene terephthalate, polyphenylene sulfide, polyarylate, polyimide, polycarbonate, cellulose acetate propionate, or the like. The substrate 100 including the polymer resin may be flexible, rollable, or bendable. The substrate 100 may have a multilayered structure including a layer including the above polymer resin and an inorganic layer.

A buffer layer 201 may be arranged on the upper surface of the substrate 100. The buffer layer 201 may prevent or reduce the penetration of impurities into a semiconductor layer Act of a transistor TFT. The buffer layer 201 may include inorganic insulating materials such as silicon nitride, silicon oxynitride, and silicon oxide and may be a layer or layers including the above inorganic insulating materials.

The pixel circuit PC may be arranged on the buffer layer 201. As described above with reference to FIG. 4, the pixel circuit PC may include a plurality of transistors and a storage capacitor. FIG. 6 illustrates the first transistor T1, the second transistor T2, the third transistor T3, and the storage capacitor Cst.

The first transistor T1 may include a semiconductor layer (hereinafter, referred to as a first semiconductor layer A1) on the buffer layer 201 and a gate electrode (hereinafter, referred to as a first gate electrode GE1) overlapping a channel area C1 of the first semiconductor layer A1. The first semiconductor layer A1 may include a silicon-based semiconductor material, for example, polysilicon.

A first gate insulating layer 203 may be arranged between the first semiconductor layer A1 and the first gate electrode GE1. The first gate insulating layer 203 may include an inorganic insulating material such as silicon oxide, silicon nitride, or silicon oxynitride and may be a layer or layers including the above inorganic insulating material.

The first gate electrode GE1 may include a conductive material including molybdenum (Mo), aluminum (Al), copper (Cu), or titanium (Ti) and may be a layer or layers including the above material. For example, the first gate electrode GE1 may have a multilayered structure including Mo/Ti or Tl/Al/Ti.

The storage capacitor Cst may include the lower electrode CE1 and the upper electrode CE2 that overlap each other. According to some embodiments, the lower electrode CE1 of the storage capacitor Cst may include the first gate electrode GE1. In other words, the first gate electrode GE1 may include the lower electrode CE1 of the storage capacitor Cst. For example, the first gate electrode GE1 and the lower electrode CE1 of the storage capacitor Cst may be integrally formed.

A first interlayer insulating layer 205 may be arranged between the lower electrode CE1 and the upper electrode CE2 of the storage capacitor Cst. The first interlayer insulating layer 205 may include an inorganic insulating material such as silicon oxide, silicon nitride, or silicon oxynitride and may be a layer or layers including the above inorganic insulating material.

The upper electrode CE2 of the storage capacitor Cst may include a low-resistance conductive material such as Mo, Al, Cu, and/or Ti and may be a layer or layers including the above material. For example, the upper electrode CE2 may have a multilayered structure including Mo/Ti or Tl/Al/Ti.

A second interlayer insulating layer 207 may be arranged on the storage capacitor Cst. The second interlayer insulating layer 207 may include an inorganic insulating material such as silicon oxide, silicon nitride, or silicon oxynitride and may be a layer or layers including the above inorganic insulating material.

A semiconductor layer (hereinafter, referred to as a third semiconductor layer A3) of the third transistor T3 may be arranged on the second interlayer insulating layer 207. The third semiconductor layer A3 may include an oxide-based semiconductor material. For example, the third semiconductor layer A3 may include a zinc (Zn) oxide-based material, for example, Zn oxide, indium (In)—Zn oxide, or gallium (Ga)—In—Zn oxide. In some embodiments, the third semiconductor layer A3 may include an In—Ga—Zn—O (IGZO), In—Sn—Zn—O (ITZO), or In—Ga—Sn—Zn—O (IGTZO) semiconductor in which metal such as In, Ga, and tin (Sn) is added to ZnO.

The third transistor T3 may include a gate electrode (hereinafter, referred to as a third gate electrode GE3) overlapping the third semiconductor layer A3. The third gate electrode GE3 may have a double-gate structure including a lower gate electrode G3A, which is arranged under the third semiconductor layer A3, and an upper gate electrode G3B arranged on the third semiconductor layer A3.

The lower gate electrode G3A may be arranged on the same layer (e.g., the first interlayer insulating layer 205) as the upper electrode CE2 of the storage capacitor Cst. The lower gate electrode G3A may include the same material as the upper electrode CE2 of the storage capacitor Cst.

The upper gate electrode G3B may be arranged on the third semiconductor layer A3 with a second gate insulating layer 209 therebetween. The upper gate electrode G3B may include a low-resistance conductive material such as Mo, Al, Cu, and/or Ti and may be a layer or layers including the above material. For example, the upper electrode CE2 may have a multilayered structure including Mo/Ti or Tl/Al/Ti. The second gate insulating layer 209 may include an inorganic insulating material such as silicon oxide, silicon nitride, or silicon oxynitride and may be a layer or layers including the above inorganic insulating material.

A third interlayer insulating layer 210 may be arranged on the upper gate electrode G3B. The third interlayer insulating layer 210 may include an inorganic insulating material such as silicon oxynitride and may be a layer or layers including the above inorganic insulating material.

FIG. 6 illustrates that the upper electrode CE2 of the storage capacitor Cst is on the same layer as the lower gate electrode G3A of the third gate electrode CE3, but one or more embodiments are not limited thereto. According to some embodiments, the upper electrode CE2 of the storage capacitor Cst may be on the same layer as the third semiconductor layer A3.

The first transistor T1 and the third transistor T3 may be electrically connected to each other through the node connection line 166. The node connection line 166 may be arranged on the third interlayer insulating layer 210. One side of the node connection line 166 may be connected to the first gate electrode GE1 of the first transistor T1, and the other side of the node connection line 166 may be connected to the third semiconductor layer A3 of the third transistor T3.

The node connection line 166 may include Al, Cu, and/or Ti and may be a layer or layers including the above material. For example, the node connection line 166 may have a multilayered structure including Mo/Ti or Tl/Al/Ti.

A first organic insulating layer 211 may be arranged on the node connection line 166. The first organic insulating layer 211 may include an organic insulating material. The organic insulating material may include acryl, Benzocyclobutene (BCB), polyimide, Hexamethyldisiloxane (HMDSO), or the like.

The data line DL and the driving power line PL may be arranged on the first organic insulating layer 211 and covered by a second organic insulating layer 213. Each of the data line DL and the driving power line PL may include Al, Cu, and/or Ti and may be a layer or layers including the above material. For example, the data line DL and the driving power line PL may have a multilayered structure including Mo/Ti or Tl/Al/Ti.

The second organic insulating layer 213 may include an organic insulating material such as acryl, BCB, polyimide, and/or HMDSO. FIG. 6 illustrates that the data line DL and the driving power line PL are formed on the first organic insulating layer 211, but one or more embodiments are not limited thereto. According to some embodiments, any one of the data line DL and the driving power line PL may be arranged on the same layer as the node connection line 166, for example, on the third interlayer insulating layer 210.

The pixel electrode 221 of the organic light-emitting diode OLED may include a reflection layer including silver (Ag), magnesium (Mg), Al, platinum (Pt), palladium (Pd), gold (Au), nickel (Ni), neodymium (Nd), iridium (Ir), chromium (Cr), or a compound thereof. According to some embodiments, the pixel electrode 221 may further include conductive oxide layers on and/or under the reflection layer. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). According to some embodiments, the pixel electrode 221 may have a tri-layer structure including an ITO layer/an Ag layer/an ITO layer.

A bank layer 215 may be arranged on the pixel electrode 221. The bank layer 215 may include an opening overlapping the pixel electrode 221 and cover an edge of the pixel electrode 221. The bank layer 215 may include an organic insulating material such as polyimide.

A spacer 217 may be formed on the bank layer 215. The spacer 217 may be formed together with the bank layer 215 through the same process or separately from the bank layer 215 through separate processes. According to some embodiments, the spacer 217 may include an organic insulating material such as polyimide. Alternatively, the bank layer 215 may include an organic insulating material such as a light-shielding dye, and the spacer 217 may include an organic insulating material such as polyimide.

The intermediate layer 222 includes an emission layer 222b. The intermediate layer 222 may include a first functional layer 222a, which is arranged under the emission layer 222b, and/or a second functional layer 222c, which is arranged on the emission layer 222b. The emission layer 222b may include a high-weight molecular or low-molecular weight organic material emitting a certain color of light. The second functional layer 222c may include an Electron Transport Layer (ETL) and/or an Electron Injection Layer (EIL). The first functional layer 222a and/or the second functional layer 222c may each include an organic material.

An opposite electrode 223 may include a conductive material having a low work function. For example, the opposite electrode 223 may include a transparent (translucent) layer including Ag, Mg, Al, Pt, Pd, Au, Ni, Nd, Ir, Cr, lithium (Li), calcium (Ca), or an alloy thereof. Alternatively, the opposite electrode 223 may further include a layer including ITO, IZO, ZnO, or In₂O₃ on the transparent (translucent) layer including the above material.

The emission layer 222b may be formed in the display area DA to overlap the pixel electrode 221 through an opening of the bank layer 215. On the contrary, organic layers included in the intermediate layer, for example, the first functional layer 222a and the second functional layer 222c, may entirely cover the display area DA. The opposite electrode 223 may entirely cover the display area DA.

A capping layer 225 may be arranged on the opposite electrode 223. The capping layer 225 may include both an inorganic material and an organic material. The capping layer 225 may include LiF, an inorganic insulating material, and/or an organic insulating material. The capping layer 225 may entirely cover the display area DA.

The organic light-emitting diode OLED including the pixel electrode 221, the intermediate layer 222, and the opposite electrode 223 may be covered by an encapsulation layer 300. The encapsulation layer 300 may include at least one organic encapsulation layer and at least one inorganic encapsulation layer. According to some embodiments, FIG. 6 illustrates that the encapsulation layer 300 includes first and second inorganic encapsulation layers 310 and 330 and an organic encapsulation layer 320 arranged therebetween. The encapsulation layer 300 may be arranged on the capping layer 225.

The first inorganic encapsulation layer 310 and the second inorganic encapsulation layer 330 may each include at least one of aluminum oxide, titanium oxide, tantalum oxide, hafnium oxide, zinc oxide, silicon oxide, silicon nitride, or silicon oxynitride The first inorganic encapsulation layer 310 and the second inorganic encapsulation layer 330 may each be a layer or layers including the above material. The organic encapsulation layer 320 may include a polymer-based material. The polymer-based material may include acryl-based resin, epoxy-based resin, polyimide, and polyethylene. According to some embodiments, the organic encapsulation layer 320 may include acrylate.

Thicknesses of the first inorganic encapsulation layer 310 and the second inorganic encapsulation layer 330 may be different from each other. The thickness of the first inorganic encapsulation layer 310 may be greater than that of the second inorganic encapsulation layer 330. Alternatively, the thickness of the second inorganic encapsulation layer 330 may be greater than or the same as that of the first inorganic encapsulation layer 310.

The input detection layer 400 may be arranged on the encapsulation layer 300. The input detection layer 400 may include touch electrodes TE arranged in the display area DA and at least one touch insulating layer. FIG. 6 illustrates that the input detection layer 400 includes first and second touch insulating layers 411 and 412 on the second inorganic encapsulation layer 300, a first conductive line 420, a third touch insulating layer 430 on the first conductive line 420, a second conductive line 440 on the third touch insulating layer 430, and a fourth touch insulating layer 450 on the second conductive line 440.

The first touch insulating layer 411, the second touch insulating layer 412, the third touch insulating layer 430, and the fourth touch insulating layer 450 may each include an inorganic insulating material and/or an organic insulating material. According to some embodiments, the first touch insulating layer 411, the second touch insulating layer 412, and the third touch insulating layer 430 may include an inorganic insulating material such as silicon oxide, silicon nitride, and/or silicon oxynitride, and the fourth touch insulating layer 450 may include an organic insulating material.

The touch electrode TE of the input detection layer 400 may have a structure in which the first conductive line 420 is connected to the second conductive line 440. Alternatively, the touch electrode TE may include any one of the first conductive line 420 and the second conductive line 440, and in this case, the third touch insulating layer 430 may be omitted.

The first conductive line 420 and the second conductive line 440 may each include Al, Cu, and/or Ti and may each be a layer or layers including the above material. For example, each of the first conductive line 420 and the second conductive line 440 may have a tri-layer structure including a Ti layer/an Al layer/a Ti layer.

Next, when referring to the intermediate area IA of FIG. 6, the first organic insulating layer 211 and the second organic insulating layer 213 may extend to the intermediate area IA. End portions of the first organic insulating layer 211 and the second organic insulating layer 213 may be separated from the first partition PW1 described below.

In the intermediate area IA, bypassing portions DL-C of data lines may be on different layers with the first organic insulating layer 211 therebetween. One of the bypassing portions DL-C of neighboring data lines may be on the first organic insulating layer 211, and another one of the bypassing portions DL-C of neighboring data lines may be under the first organic insulating layer 211. The bypassing portions DL-C of the data lines of FIG. 6 correspond to portions of the data lines DL (portions curved along the opening area OA of FIG. 5) in the intermediate area IA described above with reference to FIG. 5.

At least one partition is arranged in the intermediate area IA. According to some embodiments, FIG. 6 illustrates two partitions, but according to some embodiments, there may be three or more partitions.

The first partition PW1 and a second partition PW2 may be arranged in the intermediate area IA, but may be apart from each other in a direction towards the opening area OA from the display area DA. The first partition PW1 may be the closest to the display area DA, and the second partition PW2 may be closer to the opening area OA than the first partition wall PW1. As illustrated in FIG. 5, each of the first partition PW1 and a second partition PW2 may have a closed-loop shape surrounding the opening 10H.

As illustrated in FIG. 6 and embodiments below, because the opening 100H is formed in the substrate 100 in accordance with the opening 10H of the display panel 10, the expressions “the opening area OA,” “the opening 10H of the display panel 10,” and “the opening 100H of the substrate 100” may be interchangeably used. For example, the expression “surrounding the opening 10H of the display panel 10” indicates that the opening 100H of the substrate 100 is surrounded and/or “the opening area OA is surrounded.”

The first partition PW1 and the second partition PW2 may include insulating materials. For example, the first partition PW1 and the second partition PW2 may include organic insulating materials and may be formed together during a process of forming a plurality of insulating material layers arranged in the display area DA.

Heights of the first partition PW1 and the second partition PW2 may be identical to or different from each other. FIG. 6 illustrates that the first partition PW1 and the second partition PW2 have the same height, but according to some embodiments, the first partition PW1 and the second partition PW2 may have different heights.

At least one partition described above, for example, the first partition PW1 and the second partition PW2, may control the flow of a material forming the organic encapsulation layer 320 during a process of forming the encapsulation layer 300. For example, the organic encapsulation layer 320 may be formed by spreading a monomer in the display area DA through a process such as an inkjet and then hardening the monomer, and the partition may control a location of the organic encapsulation layer 320 by controlling the flow of the monomer. FIG. 6 illustrates that an edge 320e of the organic encapsulation layer 320 is on a side of the first partition PW1. According to some embodiments, the edge 320e of the organic encapsulation layer 320 may be on an upper surface of the first partition PW1, and thus, a portion of the organic encapsulation layer 320 may overlap the upper surface of the first partition PW1.

Because the edge 320e of the organic encapsulation layer 320 is on any one partition, for example, one side of the first partition PW1, the second inorganic encapsulation layer 330 may directly contact the first inorganic encapsulation layer 310 in the intermediate area IA. For example, the first and second inorganic encapsulation layers 310 and 330 may directly contact each other in an area between the edge 320e of the organic encapsulation layer 320 and the opening 10H of the display panel 10. According to some embodiments, FIG. 6 illustrates that the first and second inorganic encapsulation layers 310 and 330 directly contact each other in an area between the first partition PW1 and the opening 10H of the display panel 10.

The insulating layers of the input detection layer 400, for example, the first touch insulating layer 411, the second touch insulating layer 412, the third touch insulating layer 430, and the fourth touch insulating layer 450, may extend to cover the intermediate area IA.

A planarization insulating layer (or a planarization layer 401) may be arranged to cover the intermediate area IA. The planarization insulating layer 401 may be arranged only in the intermediate area IA to have a width from a first edge 401E1 and a second edge 401E2. Therefore, the planarization insulating layer 401 may have a closed-curve shape (e.g., a donut shape) surrounding the opening 10H.

The first edge 401E1 of the planarization insulating layer 401 may be towards the opening 10H of the display panel 10, and the second edge 401E2 of the planarization insulating layer 401 may be close to the display area DA. A portion of the planarization insulating layer 401, which is close to the display area DA, may overlap a portion of the organic encapsulation layer 320 while the edge 320e of the organic encapsulation layer 320 is covered, and the second inorganic encapsulation layer 330 and the first touch insulating layer 411 may be arranged between the organic encapsulation layer 320 and the planarization insulating layer 401 in a thickness direction (a z direction) of the display panel 10.

The first touch insulating layer 411 and the second touch insulating layer 412 may directly contact each other in the display area DA, but in the intermediate area IA, the first touch insulating layer 411 and the second touch insulating layer 412 may be apart from each other by the planarization insulating layer 401 therebetween in the thickness direction (the z direction).

Because at least one organic layer 220o of the intermediate layer 222 entirely covers the display area DA and the intermediate area IA, a path of moisture introduced through the opening 10H of the display panel 10 may be provided. However, according to some embodiments of the disclosure, because the organic layer 222o includes first, second, and third openings 222oh1, 222oh2, and 222oh3 in the intermediate area IA, the flow of the moisture through the organic layer 222o may be prevented or reduced.

The organic layer 222o may include separated portions 222op that are apart from each other by the first, second, and third openings 222oh1, 222oh2, and 222oh3 in the intermediate area IA. When the organic layer 222o includes the first functional layer 222a and the second functional layer 222c, the separated portions 222op of the organic layer 222o may include a portion 222ap of the first functional layer 222a and a portion 222cp of the second functional layer 222c that overlap each other.

In the intermediate area IA, a stopper layer 230 may be arranged between the organic layer 222o and at least one insulating layer (e.g., the second interlayer insulating layer 207). The stopper layer 230 may prevent or reduce the unwanted etching of insulating layers (under the stopper layer 230) and/or a portion of the substrate 100 during another etching process that is performed before the lift-off process.

The intermediate area IA may include a first area PA1, where the first openings 222oh1 are arranged, and a second area PA2, where the second openings 222oh2 are arranged. The first area PA1 may be an area between the first partition PW1 and end portions of the first and second organic insulating layers 211 and 213 extending to the intermediate area IA. For example, the first partition PW1 and the end portions of the first and second organic insulating layers 211 and 213 extending to the intermediate area IA may be apart from each other and form a valley, and the first area PA1 may correspond to the bottom of the valley. The second area PA2 may be an area between the first partition PW1 and the second partition PW2. For example, the first partition PW1 and the second partition PW2, which are apart from each other, may form a sort of a valley, and the second area PA2 may correspond to the bottom of the valley. According to some embodiments, the intermediate area IA may include a third area PA3 where the third openings 222oh3 are arranged. The third area PA3 may be at least a portion of an area between the second partition PW2 and the opening 10H.

The stopper layer 230 may include through holes 230oh (hereinafter, referred to as third through holes) corresponding to the first, second, and third openings 222oh1, 222oh2, and 222oh3 of the organic layer 222o. The stopper layer 230 may include a first portion 230a and a second portion 230b, which are arranged on both sides of the third through holes 230oh therebetween, and a third portion 230c arranged between the third through holes 230oh.

The separated portions 222op of the organic layer 222o, which do not overlap the first, second, and third openings 222oh1, 222oh2, and 222oh3, may be directly on the first portion 230a, the second portion 230b, and the third portion 230c of the stopper layer 230, respectively.

An upper surface of any one of the inorganic insulating layers (e.g., the first gate insulating layer 203, the first interlayer insulating layer 205, and the second interlayer insulating layer 207) may be exposed through the first, second, and third openings 222oh1, 222oh2, and 222oh3 of the organic layer 222o and through holes of lower layers corresponding thereto, and the first inorganic encapsulation layer 310 may directly contact the first gate insulating layer 203 exposed. For example, as illustrated in FIG. 6, the first interlayer insulating layer 205 may be exposed through the first, second, and third openings 222oh1, 222oh2, and 222oh3 of the organic layer 222o, the third through holes 230oh of the stopper layer 230, and the first through holes 207oh of the second interlayer insulating layer 207, and the first inorganic encapsulation layer 310 may directly contact the first interlayer insulating layer 205. The first interlayer insulating layer 205 may include an inorganic insulating material, and the contact between the first inorganic encapsulation layer 310 and the first interlayer insulating layer 205 may locally prevent or prevent the moisture from flowing.

Each of the first and second openings 222oh1 and 222oh2 of the organic layer 222o may include at least two openings having the same center but different diameters. As illustrated in FIG. 6, for example, the first openings 222oh1 of the organic layer 222o may include a 1-1 opening oh1-1 and a 1-2 opening oh1-2 that are apart from each other, and the second openings 222oh2 may include a 2-1 opening oh2-1 and a 2-2 opening oh2-2 that are apart from each other. A width d1 of the 1-1 opening oh1-1 and a width d2 of the 1-2 opening oh1-2 may each be between about 1.8 μm and about 30 μm and may be the same as or different from each other. According to some embodiments, the third openings 222oh3 may include at least two openings oh3-1 and oh3-3 having the same center and different diameters. A width of each of the third openings 222oh3 may be the same as the width of the 1-1 opening oh1-1 or the 1-2 opening oh1-2.

Each of the openings 222oh1, 222oh2, and 222oh3 may extend along the rim of the opening 10H, and on the plan view, the openings 222oh1, 222oh2, and 222oh3 may each have a closed-loop shape completely surrounding the opening 10H. Therefore, the separated portions 222op of the organic layer 222o, which are apart from each other by the openings 222oh1, 222oh2, and 222oh3, may be apart from each other, and the separated portions 222op may have a closed-loop shape entirely surrounding the opening area OA. On a cross-sectional view, the separated portions 222op of the organic layer 222o may cover the first partition PW1, the second partition PW2, or a portion between the second partition PW2 and the opening 10H. The separated portions 222op of the organic layer 222o, which are on the first partition PW1, the second partition PW2, or the portion between the second partition PW2 and the opening 10H, may directly contact each other and may be covered by the first inorganic encapsulation layer 310.

The opposite electrode 223, which entirely covers the display area DA, may extend towards the intermediate area IA, but an edge portion 223ep of the opposite electrode 223 may be between the first partitions PW1.

According to some embodiments, the edge portion 223ep of the opposite electrode 223 may be a portion of the opposite electrode 223 that is the closest to the opening 10H, and a layer corresponding to the opposite electrode 223 may not exist in an area from the edge portion 223ep of the opposite electrode 223 to the opening 10H.

In other words, a layer having the same material and structure as the opposite electrode 223 may not exist between the edge portion 223ep of the opposite electrode 223 and the opening 10H.

Like the opposite electrode 223, the capping layer 225 may extend to the intermediate area IA, but one edge of the capping layer 225 may be between the display area DA and any one partition. In other words, a layer having the same material and structure as the capping layer 225 may not exist in an area from one edge of the capping layer 225 to the opening 10H.

The edge portion 223ep of the opposite electrode 223 may overlap and may be covered by an organic layer, for example, the organic encapsulation layer 320. The opposite electrode 223 may be formed by forming an opposite electrode material layer, which entirely covers the display area DA and the intermediate area IA, and then removing a portion of the opposite electrode material layer arranged in the intermediate area IA. A portion of the opposite electrode material layer may be removed through a laser lift-off process, and the edge portion 223ep of the opposite electrode 223 may have an irregular shape because of laser.

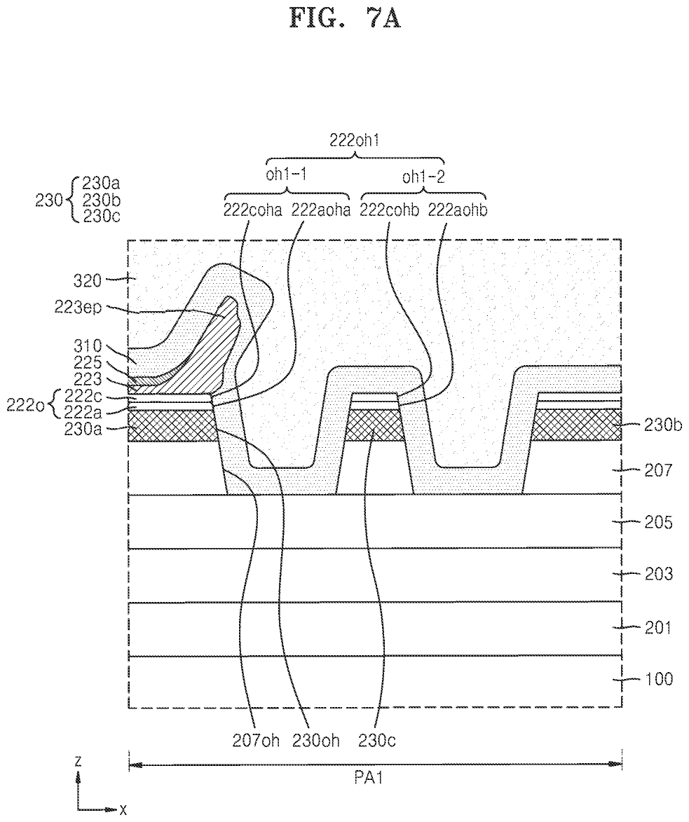

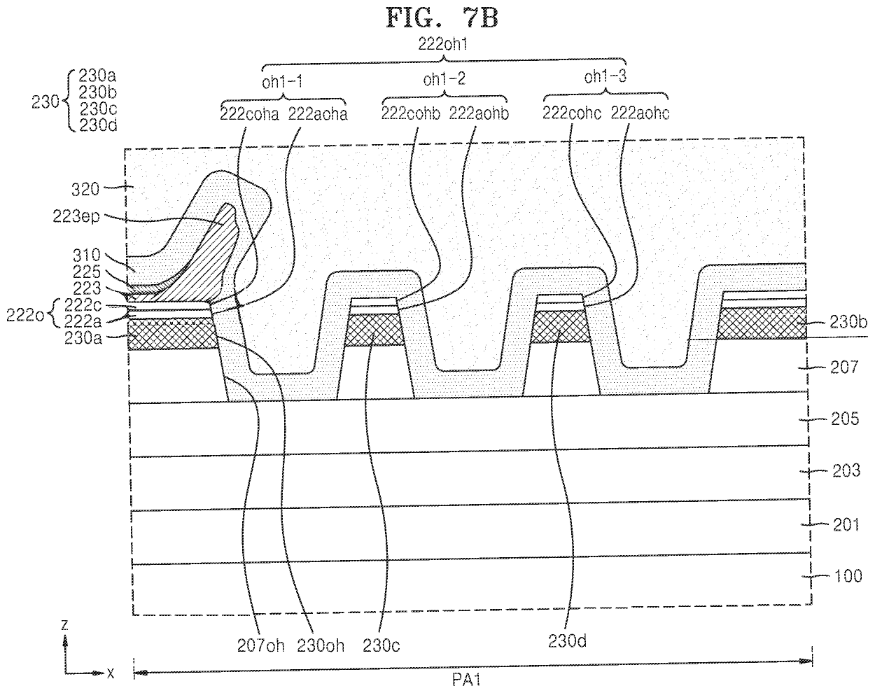

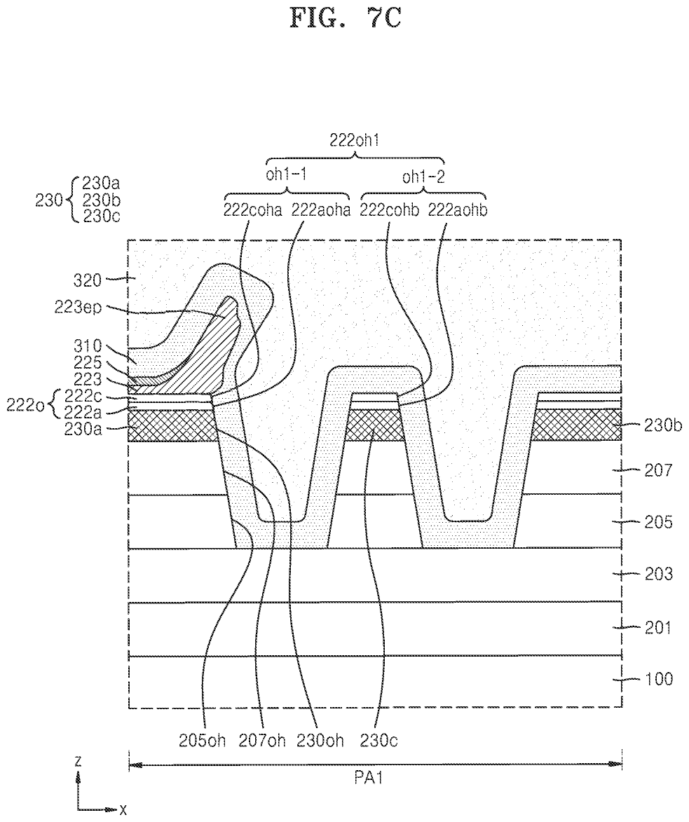

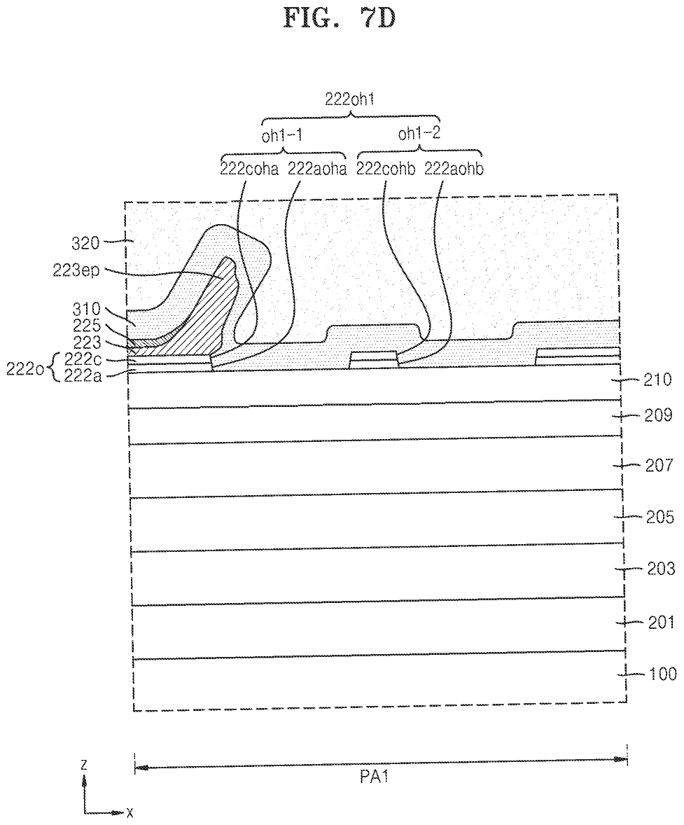

FIGS. 7A to 7D are cross-sectional view of an enlarged portion VII of FIG. 6.

The openings 222oh1, 222oh2, and 222oh3 of the organic layer 222o may be formed through the laser lift-off process using the sacrificial layer, and in this case, the sacrificial layer may include any one selected from among the gate electrode of the transistor included in the pixel circuit PC and the electrodes of the storage capacitor Cst. According to some embodiments, during manufacturing processes, the sacrificial layer described above may be covered by at least one insulating layer, and a through hole may be arranged under the openings 222oh1, 222oh2, and 222oh3 of the organic layer 222o, which are formed through the laser lift-off process, the through hole being formed in at least one insulating layer. FIGS. 7A to 7D illustrate the first openings 222oh1 arranged in the first area PA1 that is an area between the first and second organic insulating layers 211 and 213 and the first partition PW1 and extending to the intermediate area IA.

Referring to FIG. 7A, the organic layer 222o is divided into the separated portions 222op by the first openings 222oh1 in the first area PA1. The first openings 222oh1 may include the 1-1 opening oh1-1 and the 1-2 opening oh1-2 that are apart from each other. The 1-1 opening oh1-1 may be formed as a first hole 222aoha of the first functional layer 222a overlaps a first hole 222coha of the second functional layer 222c, and the 1-2 opening oh1-2 may be formed as a second hole 222aohb of the first functional layer 222a overlaps a second hole 222cohb of the second functional layer 222c.

The stopper layer 230 may include the third through holes 230oh corresponding to the openings 222oh1, 222oh2, and 222oh3 of the organic layer 222o. The stopper layer 230 may include the first portion 230a and the second portion 230b, which are arranged with the third through holes 230oh therebetween, and the third portion 230c arranged between the third through holes 230oh.

The first interlayer insulating layer 205 may be exposed through the 1-1 opening oh1-1, the 1-2 opening oh1-2, the third through holes 230oh of the stopper layer 230 corresponding to the 1-1 opening oh1-1 and the 1-2 opening oh1-2, and the first through holes 207oh of the second interlayer insulating layer 207, and the first inorganic encapsulation layer 310 may directly contact the first interlayer insulating layer 205. The first interlayer insulating layer 205 may include an inorganic insulating material, and the contact between the first inorganic encapsulation layer 310 and the first interlayer insulating layer 205 may locally prevent or reduce the flow of the moisture. To prevent or reduce the occurrence of cracks because of the lifting of the first inorganic encapsulation layer 310 or insufficient prevention of the flow of the moisture, a remaining sacrificial layer may not exist or may be reduced on the first interlayer insulating layer 205.

The edge portion 223ep of the opposite electrode 223 may overlap or may be covered by an organic layer, for example, the organic encapsulation layer 320. The opposite electrode 223 may be formed by forming the opposite electrode material layer, which entirely covers the display area DA and the intermediate area IA, and then removing a portion of the opposite electrode material layer arranged in the intermediate area IA. A portion of the opposite electrode material layer may be removed through the laser lift-off process, and the edge portion 223ep of the opposite electrode 223 may have an irregular shape because of laser. As illustrated in FIG. 7A, for example, the edge portion 223ep of the opposite electrode 223 may have burrs formed through the laser lift-off process. The edge portion 223ep of the opposite electrode 223 may extend in an oblique direction further from the upper surface of the substrate 100, and a cross-section of the edge portion 223ep may have uneven portions.

Because of a shape of the edge portion 223ep of the opposite electrode 223, a thickness of the first inorganic encapsulation layer 310 on the opposite electrode 223 may not be uniform. As illustrated in FIG. 7A, for example, the first inorganic encapsulation layer 310 may include an upper surface that is convex upwards according to the shape of the edge portion 223ep of the opposite electrode 223.

The first inorganic encapsulation layer 310 may have relatively great step coverage. However, because the edge portion 223ep of the opposite electrode 223 under the first inorganic encapsulation layer 310 has an irregular shape, the first inorganic encapsulation layer 310 may include a portion, which has a locally small density, and/or a thin portion. In this case, cracks may appear in the first inorganic encapsulation layer 310 and may propagate, but according to some embodiments, because the organic encapsulation layer 320 overlaps and/or covers the edge portion 223ep of the opposite electrode 223, the above problem may be prevented or reduced.

Referring to FIG. 7B, the first openings 222oh1 may include the 1-1 opening oh1-1, the 1-2 opening oh1-2, and the 1-3 opening oh1-3 that are apart from each other. The 1-1 opening oh1-1 may be formed as the first hole 222aoha of the first functional layer 222a overlaps the first hole 222coha of the second functional layer 222c, the 1-2 opening oh1-2 may be formed as the second hole 222aohb of the first functional layer 222a overlaps the second hole 222cohb of the second functional layer 222c, and the 1-3 opening oh1-3 may be formed as a third hole 222aohc of the first functional layer 222a overlaps a third hole 222cohc of the second functional layer 222c.

The stopper layer 230 may include the third through holes 230oh corresponding to the openings 222oh1, 222oh2, and 222oh3 of the organic layer 222o. The stopper layer 230 may include the first portion 230a and the second portion 230b, which are arranged with the third through holes 230oh therebetween, and the third portion 230c and a fourth portion 230d, which are arranged between the third through holes 230oh.

The first interlayer insulating layer 205 may be exposed through the 1-1 opening oh1-1, the 1-2 opening oh1-2, and the 1-3 opening oh1-3, the third through holes 230oh of the stopper layer 230 corresponding thereto, and an opening 207a of the second interlayer insulating layer 207. Therefore, the first inorganic encapsulation layer 310 may directly contact the first interlayer insulating layer 205 on at least three portions in the first area PA1.

Referring to FIG. 7C, the first openings 222oh1 may include the 1-1 opening oh1-1 and the 1-2 opening oh1-2 that are apart from each other. The first gate insulating layer 203 may be exposed through the 1-1 opening oh1-1, the 1-2 opening oh1-2, the third through holes 230oh of the stopper layer 230, which correspond to the 1-1 opening oh1-1, the 1-2 opening oh1-2, the second through holes 207oh of the second interlayer insulating layer 207, and the first through holes 205oh of the first interlayer insulating layer 205, and the first inorganic encapsulation layer 310 may directly contact the first gate insulating layer 203. The first gate insulating layer 203 may include an inorganic insulating material, and the contact between the first inorganic encapsulation layer 310 and the first gate insulating layer 203 may locally prevent or reduce the flow of moisture. To prevent or reduce the occurrence of cracks because of the lifting of the first inorganic encapsulation layer 310 or insufficient prevention of the flow of the moisture, a remaining sacrificial layer may not exist or may be reduced on the first gate insulating layer 203.

According to some embodiments, as illustrated in FIG. 7B, the first openings 222oh1 may include at least three openings, and the first gate insulating layer 203 may be exposed through the openings and the third through holes 230oh of the stopper layer 230, the first through holes 207oh of the second interlayer insulating layer 207, and the second through holes 205oh of the first interlayer insulating layer 205 that correspond to the openings.

Referring to FIG. 7D, the second gate insulating layer 209 and the third interlayer insulating layer 210 may be arranged in the first area PA1. That is, the second gate insulating layer 209 and the third interlayer insulating layer 210 may extend to cover from the display area DA to the intermediate area IA and may cover the first area PA1. The first openings 222oh1 may include the 1-1 opening oh1-1 and the 1-2 opening oh1-2 that are apart from each other. The 1-1 opening oh1-1 may be formed as the first hole 222aoha of the first functional layer 222a overlaps the first hole 222coha of the second functional layer 222c, and the 1-2 opening oh1-2 may be formed as the second hole 222aohb of the first functional layer 222a overlaps the second hole 222cohb of the second functional layer 222c.

According to some embodiments, the stopper layer 230 may be omitted. Therefore, the third interlayer insulating layer 210 may be exposed through the 1-1 opening oh1-1 and the 1-2 opening oh1-2, and the first inorganic encapsulation layer 310 may directly contact the third interlayer insulating layer 210. The third interlayer insulating layer 210 may include an inorganic insulating material, and the contact between the first inorganic encapsulation layer 310 and the third interlayer insulating layer 210 may locally prevent or reduce the flow of the moisture. To prevent or reduce the occurrence of cracks because of the lifting of the first inorganic encapsulation layer 310 or insufficient prevention of the flow of the moisture, a remaining sacrificial layer may not exist or may be reduced on the third interlayer insulating layer 210.

According to some embodiments, as illustrated in FIG. 7B, the first openings 222oh1 may include at least three openings, and the third interlayer insulating layer 210 may be exposed through each opening.

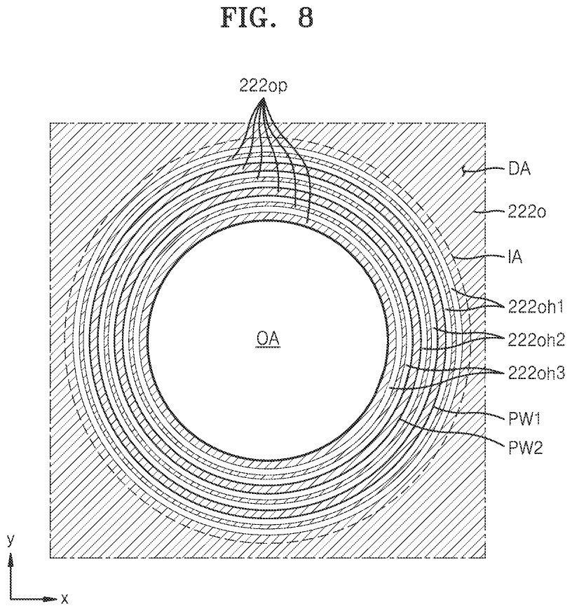

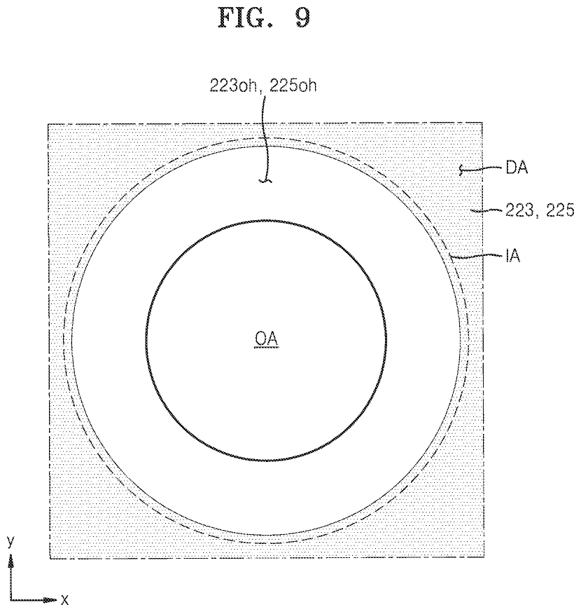

FIG. 8 is a plan view of at least one organic layer of FIG. 6, and FIG. 9 is a plan view of an opposite electrode of FIG. 6.

Referring to FIGS. 8 and 9, the first, second, and third openings 222oh1, 222oh2, and 222oh3 of the organic layer 222o and an electrode opening 223oh of the opposite electrode 223 may respectively extend along the rim of the opening 10H and may each have a closed-loop shape completely surrounding the opening 10H on a plan view. As described above, the first openings 222oh1 in the first area PA1 (see FIG. 6) and the second openings 222oh2 in the second area PA2 (see FIG. 6) may each include openings. According to some embodiments, the third openings 222oh3 in the third area PA3 (see FIG. 6) may include openings, and the width of each of the third openings 222oh3 may be the same as the width of each of the first openings 222oh1. Therefore, the separated portions 222op of the organic layer 222o, which are separated by the openings 222oh1, 222oh2, and 222oh3, may have closed-loop shapes that are separated from each other and entirely surround the opening area OA.

The organic layer 222o may include the openings 222oh1, 222oh2, and 222oh3, and the opposite electrode 223 may include the electrode opening 223oh. The electrode opening 223oh may overlap the openings 222oh1, 222oh2, and 222oh3 of the organic layer 222o. In other words, in the electrode opening 223oh, the openings 222oh1, 222oh2, and 222oh3 of the organic layer 222o and the separated portions 222op, which are apart from each other by the openings 222oh1, 222oh2, and 222oh3, may be arranged. According to some embodiments, the electrode opening 223oh may cover the 1-1 opening oh1-1 (see FIG. 7A) that is the closest to the display area DA from among the first openings 222oh1. Therefore, the edge portion 223ep of the opposite electrode 223 may be on the end portions of the first and second organic insulating layers 211 and 213 in the first area PA1, and the organic encapsulation layer 230 may overlap the edge portion 223ep of the opposite electrode 223.

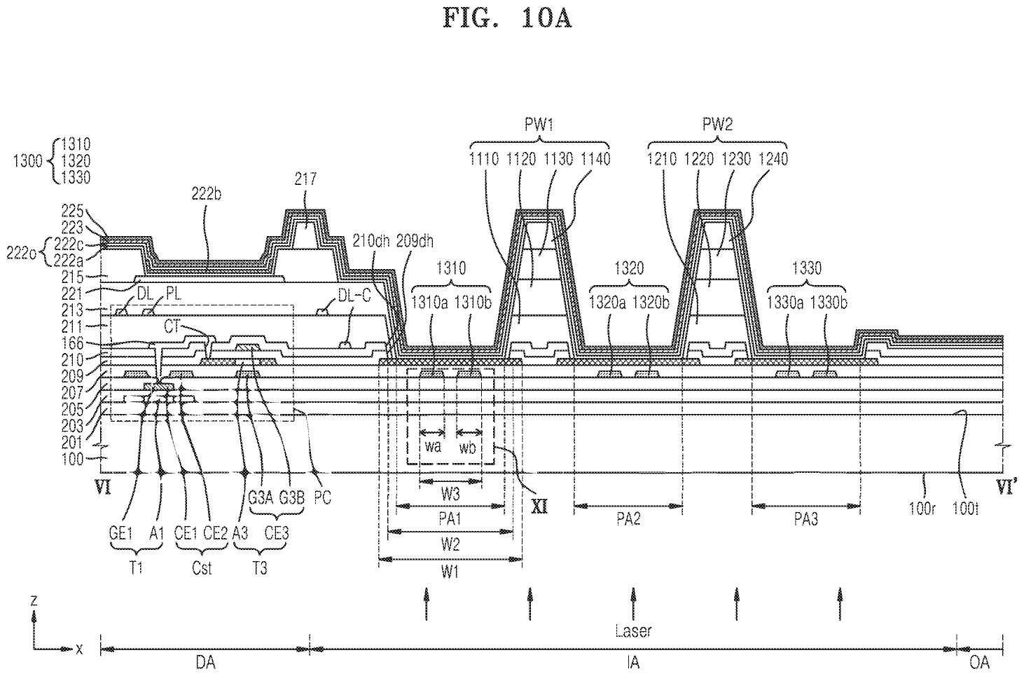

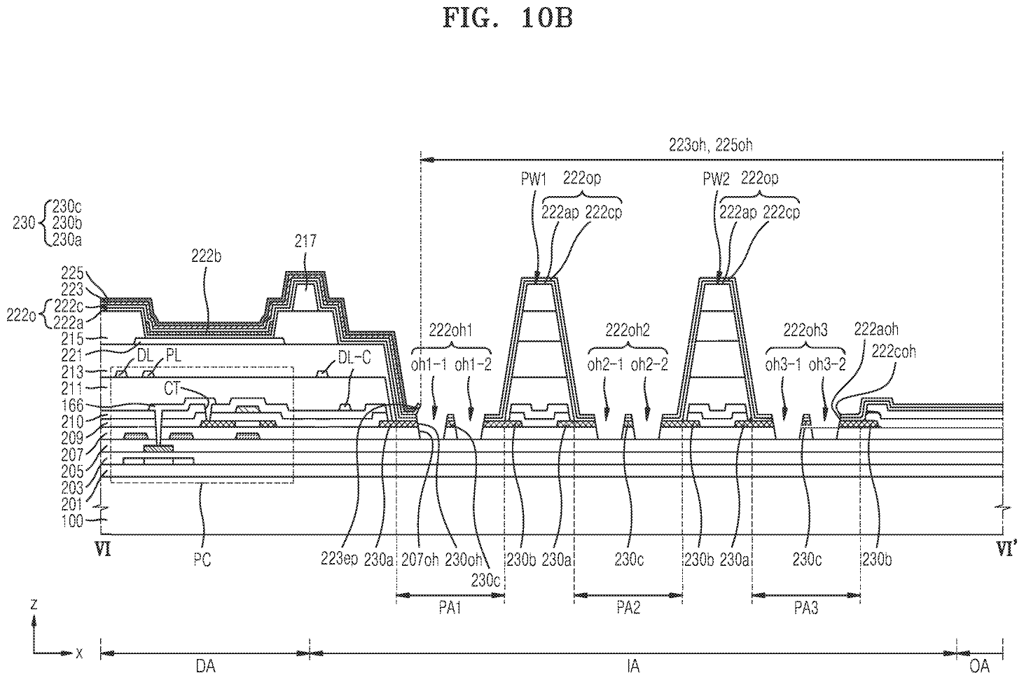

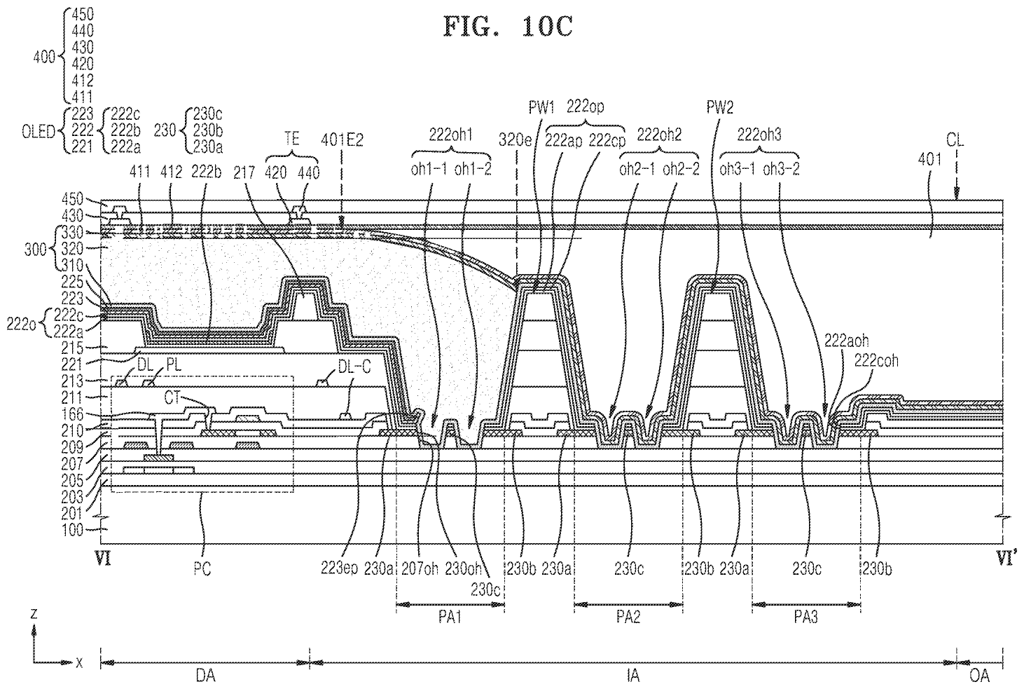

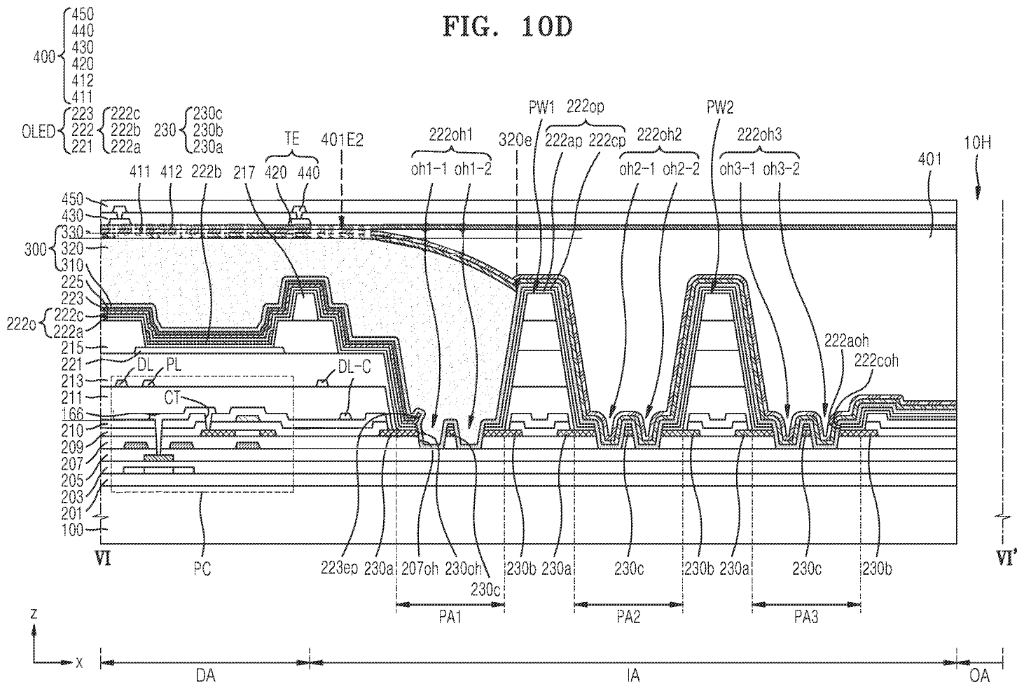

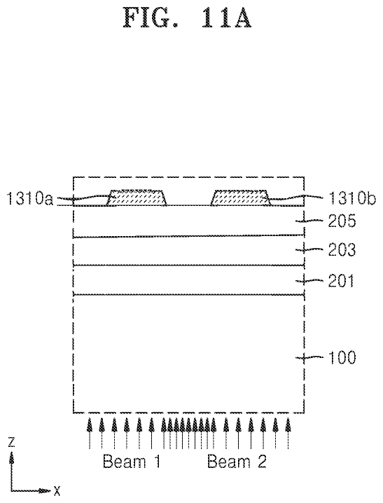

FIGS. 10A to 10D are cross-sectional views of a method of manufacturing a display panel, according to some embodiments.

Referring to FIG. 10A, the pixel circuit PC including the transistor and the storage capacitor Cst is formed on the substrate 100 to be arranged in the display area DA. As described above with reference to FIG. 6, FIG. 10A illustrates that the pixel circuit PC includes the first and third transistors T1 and T3 and the storage capacitor Cst. Before the pixel circuit PC is formed, the buffer layer 201 may be formed.

A process of forming the pixel circuit PC may include a process of forming metal layers forming the transistors and the storage capacitor Cst and a process of forming the insulating layers. The first gate insulating layer 203 and the first interlayer insulating layer 205 may entirely cover the display area DA, the intermediate area IA, and the opening area OA.

Sacrificial layers 1300 may be formed in the intermediate area IA. The sacrificial layers 1300 may include a plurality of first lines 1310 in the first area PA1 and a plurality of second lines 1320 in the second area PA2. According to some embodiments, the sacrificial layers 1300 further include a plurality of third lines 1330 in the third area PA3. The first lines 1310 may include a 1-1 line 1310a and a 1-2 line 1310b having the same center and different diameters, and the second lines 1320 may include a 2-1 line 1320a and a 2-2 line 1320b having the same center and different diameters. According to some embodiments, the third lines 1330 may include a 3-1 line 1330a and a 3-2 line 1330b having the same center and different diameters. A width of each of the 3-1 line 1330a and the 3-2 line 1330b may be the same as a width of the 1-1 line 1310a and/or a width of the 1-2 line 1310b. Referring to FIG. 10A, the first lines 1310 include two lines 1310a and 1310b, but one or more embodiments are not limited thereto. For example, the first lines 1310 may include three lines. The number of lines forming the first lines 1310 and the second lines 1320 may be the same or different.

The sacrificial layer 1300 may be formed together through the same process as one of the metal layers forming the pixel circuit PC, for example, the first gate electrode GE1 of the first transistor T1, the upper electrode CE2 of the storage capacitor Cst, the upper gate electrode G3B of the third transistor T3, and/or the node connection line 166. The sacrificial layer 1300 may include the same material as the metal layer that is formed through the same process as the sacrificial layer 1300. According to some embodiments, the sacrificial layer 1300 may include Mo and/or Cu, and according to some embodiments, the sacrificial layer 1300 may have a multilayered structure including Mo/Ti or Tl/Al/Ti. FIG. 10A illustrates that the sacrificial layer 1300 is on the same layer as the upper electrode CE2 of the storage capacitor Cst (e.g., on the first interlayer insulating layer 205). The sacrificial layer 1300 may include the same material as the upper electrode CE2 of the storage capacitor Cst.

At least one insulating layer may be formed on the sacrificial layer 1300, and FIG. 10A illustrates that the second interlayer insulating layer 207 is formed to cover the sacrificial layer 1300.

Then, the stopper layer 230 may be formed on the second interlayer insulating layer 207. The stopper layer 230 may be formed through the same process as the third semiconductor layer A3. The stopper layer 230 may be on the same layer as the third semiconductor layer A3 (e.g., the second interlayer insulating layer 207) and may include the same material as the third semiconductor layer A3.

At least one insulating layer, for example, the inorganic insulating layers such as the second gate insulating layer 209 and the third interlayer insulating layer 210, may be formed on the stopper layer 230. The second gate insulating layer 209 and the third interlayer insulating layer 210 may include dummy holes 209dh and 210dh overlapping the stopper layer 230. The dummy holes 209dh and 210dh may be formed together through a process of forming a contact hole CT for connecting the node connection line 166 to the third semiconductor layer A3. The stopper layer 230 may prevent or reduce damage to layers (e.g., layers including insulating materials) under the stopper layer 230 during an etching process of forming the dummy holes 209dh and 210dh and the contact hole CT and/or an etching process of forming a pixel electrode 221 described below.

A width W1 of the stopper layer 230 may be greater than widths W2 of the dummy holes 209dh and 210dh. Therefore, both edges of the stopper layer 230 may be covered by the inorganic insulating layers, for example, the second gate insulating layer 209 and the third interlayer insulating layer 210. The stopper layer 230 may entirely cover the sacrificial layer 1300, and the width W1 of the stopper layer 230 may be greater than the entire width W3 of lines formed in one area (e.g., the first area PA1).

According to some embodiments, when the sacrificial layer 1300 is formed on the third interlayer insulating layer 210, the process of forming the stopper layer 230 and the dummy holes 209dh and 210dh may be omitted.

Then, the first organic insulating layer 211 and the second organic insulating layer 213 are formed. The first organic insulating layer 211 and the second organic insulating layer 213 may be in the display area DA, but portions of the first organic insulating layer 211 and the second organic insulating layer 213 may extend to the intermediate area IA. An end portion of each of the first organic insulating layer 211 and the second organic insulating layer 213 may be in the intermediate area IA, but may be separated from the first partition PW1.

Before the second organic insulating layer 213 is formed, the bypassing portions DL-C of the data lines may be formed on and under the first organic insulating layer 211, respectively.

In the display area DA, the pixel electrode 221 is formed on the second organic insulating layer 213, and the bank layer 215 and the spacer 217 are formed on the pixel electrode 221. The pixel electrode 221 may be formed by forming an electrode material layer forming the pixel electrode 221 and then etching (e.g., wet-etching) the electrode material layer.

In the intermediate layer IA, the first and second partitions PW1 and PW2 may be formed. The first and second partitions PW1 and PW2 may be formed together through a process of forming the first organic insulating layer 211, second organic insulating layer 213, the bank layer 215, and the spacer 217.

The first partition PW1 may have a structure in which a first sub-partition wall layer 1110, a second sub-partition wall layer 1120, a third sub-partition wall layer 1130, and a fourth sub-partition wall layer 1140 are stacked. The second partition PW2 may have a structure in which a first sub-partition wall layer 1210, a second sub-partition wall layer 1220, a third sub-partition wall layer 1230, and a fourth sub-partition wall layer 1240 are stacked. The first sub-partition wall layers 1110 and 1210 of the first and second partitions PW1 and PW2 may include the same material as the first organic insulating layer 211 through the same process as the first organic insulating layer 211. The second sub-partition wall layers 1120 and 1220 may include the same material as the second organic insulating layer 213 through the same process as the second organic insulating layer 213. The third sub-partition wall layers 1130 and 1230 may include the same material as the bank layer 215 through the same process as the bank layer 215, and the fourth sub-partition wall layers 1140 and 1240 may include the same material as the spacer 217 through the same process as the spacer 217. Some layers forming the first and second partitions PW1 and PW2 may be omitted. Both sides of the first and second partitions PW1 and PW2 may be on the stopper layers 230 that are apart from each other.

The emission layer 222b is formed in an opening of the bank layer 215 that covers the edge of the pixel electrode 221 but exposes a portion of the pixel electrode 221. The first functional layer 222a may be formed under the emission layer 222b, and/or the second functional layer 222c may be formed on the emission layer 222b. Then, the opposite electrode 223 and the capping layer 225 may be formed.

Unlike the emission layer 222b, the first functional layer 222a, the second functional layer 222c, the opposite electrode 223, and the capping layer 225 may entirely cover the substrate 100. FIG. 10A illustrates that the first functional layer 222a, the second functional layer 222c, the opposite electrode 223, and the capping layer 225 are arranged on the stopper layer 230 through the pixel electrode 221 and the dummy holes 209dh and 210dh. The first functional layer 222a, the second functional layer 222c, the opposite electrode 223, and the capping layer 225 may be arranged on the first and second partitions PW1 and PW2.

When the first functional layer 222a, the second functional layer 222c, and the opposite electrode 223, which are common layers, entirely cover the upper surface of the substrate 100, cracks may appear, or moisture may be introduced to the light-emitting diode. To prevent or reduce the cracks or the introduction of moisture, portions of the organic layer 222o (e.g., portions of the first and second functional layers 222a and 222c) and a portion of the opposite electrode 223 may be removed in the intermediate area IA. To this end, the laser is irradiated onto the substrate 100.

The laser may be irradiated in a direction from a lower surface 100r of the substrate 100 to an upper surface 100t thereof. The laser may be irradiated multiple times, and when the laser is irradiated multiple times, a laser type, a laser output, and/or a laser irradiation range may change. In some embodiments, the laser output may be set based on a band gap of the opposite electrode 223. A diameter of a laser beam may be determined according to a width of each line (e.g., 1310a, 1310b, 1320a and 1320b). For example, the diameter of the laser beam may be greater than a width wa of the 1-1 line 1310a and a width wb of the 1-2 line 1310b.

A portion of the opposite electrode 223 in the intermediate area IA and a portion of the capping layer 225 in the intermediate area IA may be removed through the laser irradiation (the laser lift-off process). FIG. 10B illustrates the electrode opening 223oh of the opposite electrode 223 and the opening 225oh of the capping layer 225 that are formed by removing a portion of the opposite electrode 223 and a portion of the capping layer 225 in the intermediate area IA. Each of the electrode opening 223oh of the opposite electrode 223 and the opening 225oh of the capping layer 225 is an opening in the intermediate area IA. The electrode opening 223oh and the opening 225oh of the capping layer 225 may occupy most of the opening area OA and the intermediate area IA.

According to some embodiments, the edge portion 223ep of the opposite electrode 223, which defines the outline of the electrode opening 223oh, may be arranged between the first partition PW1 and the end portions of the first organic insulating layer 211 and the second organic insulating layer 213, and an edge of the capping layer 225, which defines an outline of the opening 225oh of the capping layer 225, may be on the edge portion 223ep of the opposite electrode 223. The outlines of the electrode opening 223oh and the opening 225oh of the capping layer 225 may be closer to the display area DA than the first partition PW1. In other words, the first and second partitions PW1 and PW2 may be in the electrode opening 223oh and the opening 225oh of the capping layer 225.

During the laser lift-off process described above, the sacrificial layer 1300 may be heated at a certain temperature by absorbing the laser, and layers on the sacrificial layer 1300 may be removed together with the sacrificial layer 1300. According to embodiments of the disclosure, the sacrificial layer 1300 may be formed in the above-described process of forming the pixel circuit PC without a separate mask process of forming the sacrificial layer 1300. Therefore, a thickness of the sacrificial layer 1300 may be determined according to a thickness of a metal layer forming the pixel circuit PC. When the thickness of the sacrificial layer 1300 increases, laser outputs for the laser lift-off may increase, and thus, the substrate 100 may be damaged or carbonized so that the reliability of the display panel 10 may decrease. Because an edge portion of the sacrificial layer 1300 is effectively heated and removed through the laser irradiation, the sacrificial layer 1300 includes the lines 1310a, 1310b, 1320a, and 1320b having smaller widths than that of the laser beam, and thus, the laser lift-off may be performed without any remaining sacrificial layer 1300 through a small laser output.

A portion of at least one insulating layer arranged on the sacrificial layer 1300 may also be removed together with the sacrificial layer 1300. As illustrated in FIG. 10A, for example, when the sacrificial layer 1300 is on the same layer as the upper electrode CE2 of the storage capacitor Cst, a portion of the second interlayer insulating layer 207, a portion of the stopper layer 230, and a portion of the organic layer 222o (in detail, a portion of the first functional layer 222a and a portion of the second functional layer 222c) on the sacrificial layer 1300 may also be removed. FIG. 10B illustrates the openings 222oh1, 222oh2, and 222oh3 of the organic layer 222o, the third through holes 230oh of the stopper layer 230 and the first through holes 207oh of the second interlayer insulating layer 207 under the openings 222oh1, 222oh2, and 222oh3.

When the organic layer 222o includes the first functional layer 222a and the second functional layer 222c, the first opening 222oh of the organic layer 222o may be formed as the opening 222aoh of the first functional layer 222a overlaps the opening 222coh of the second functional layer 222c. The stopper layer 230 may include the first portion 230a and the second portion 230b, which are arranged with the third through holes 230oh therebetween, and the third portion 230c arranged between the third through holes 230oh.

The organic layer 222o may include the separated portions 222op that are apart from each other by the openings 222oh1, 222oh2, and 222oh3. When the organic layer 222o includes the first functional layer 222a and the second functional layer 222c, the separated portions 222op may include separated portions 222ap of the first functional layer 222a and separated portions 222cp of the second functional layer 222c. The separated portions 222op of the organic layer 222o may be apart from each other by the openings 222oh1, 222oh2, and 222oh3. The first and second openings 222oh1 and 222oh2 are arranged on both sides of the first partition PW1, and the second and third openings 222oh2 and 222oh3 are arranged on both sides of the second partition PW2. Therefore, the first and second partitions PW1 and PW2 may be covered by the separated portions 222op, for example, the separated portions 222ap of the first functional layer 222a and the separated portions 222cp of the second functional layer 222c.

Referring to FIG. 10C, the encapsulation layer 300 and the input detection layer 400 may be formed on the substrate 100 on which the structure described with reference to FIG. 10B is formed.

The first inorganic encapsulation layer 310 of the encapsulation layer 300 entirely covers the substrate 100. The first inorganic encapsulation layer 310 may be formed through a chemical vapor deposition method. Because the sacrificial layer 1300 is removed in the laser lift-off process described above, the first inorganic encapsulation layer 310 may directly contact an upper surface of the first interlayer insulating layer 205 exposed through the first through holes 207oh of the second interlayer insulating layer 207.

Because the first inorganic encapsulation layer 310 has relatively great step coverage, the first inorganic encapsulation layer 310 may cover the edge portion 223ep of the opposite electrode 223. As described above with reference to FIG. 7, although the first inorganic encapsulation layer 310 covers the edge portion 223ep of the opposite electrode 223, the occurrence possibility of cracks may be relatively high around the edge portion 223ep. However, because the edge portion 223ep of the opposite electrode 223 overlaps or is covered by the organic encapsulation layer 320, the above problem may be prevented or reduced.

The organic encapsulation layer 320 may be formed by spreading a monomer through a process such as an inkjet and then hardening the monomer, and the organic encapsulation layer 320 may include resin formed as the monomer is hardened. Specific materials of the organic encapsulation layer 320 are described above.

The second inorganic encapsulation layer 330 may be formed on the organic encapsulation layer 320 and may be formed through the chemical vapor deposition method like the first inorganic encapsulation layer 310. The second inorganic encapsulation layer 330 may directly contact the first inorganic encapsulation layer 310 in a portion of the intermediate area IA where the organic encapsulation layer 320 is not formed and in the opening area OA. For example, the second inorganic encapsulation layer 330 may directly contact the first inorganic encapsulation layer 310 in a portion between the edge 320e of the organic encapsulation layer 320 and the opening area OA, and the possibility of the penetration of moisture may decrease or may be prevented.

Then, the first touch insulating layer 411 may be formed, and the planarization insulating layer 401 may be formed on the first touch insulating layer 411. The planarization insulating layer 401 may be formed in the intermediate area IA and the opening area OA. The planarization insulating layer 401 may not cover the display area DA. In the manufacturing processes illustrated in FIG. 10C, the planarization insulating layer 401 may only exist in the intermediate area IA and the opening area OA. Then, the second touch insulating layer 412, the third touch insulating layer 430, and the fourth touch insulating layer 450 may be formed.

When the opening area OA is cut along a cutting line CL by using a method such as laser cutting, the display panel 10 may include the opening 10H formed in the opening area OA, as illustrated in FIG. 10D.

According to the processes described with reference to FIGS. 10A to 10D, the sacrificial layer 1300 may be formed through the same process as the upper electrode CE2 of the storage capacitor Cst. Therefore, it is described that the sacrificial layer 1300 includes the same material on the same layer as the upper electrode CE2 of the storage capacitor Cst, but one or more embodiments are not limited thereto.

As described above, according to some embodiments, the sacrificial layer 1300 may be formed through the same process as the first gate electrode GE1 of the first transistor T1, the upper electrode CE2 of the storage capacitor Cst, the upper gate electrode G3B of the third transistor T3, and/or the node connection line 166. For example, the sacrificial layer 1300 may be on the same layer as the first gate electrode GE1 of the first transistor T1, the upper electrode CE2 of the storage capacitor Cst, the upper gate electrode G3B of the third transistor T3, and/or the node connection line 166. The sacrificial layer 1300, which is formed on the same layer as the first gate electrode GE1 of the first transistor T1, the upper electrode CE2 of the storage capacitor Cst, the upper gate electrode G3B of the third transistor T3, and/or the node connection line 166, may be removed as described above with reference to FIG. 10B, and in this case, the display panel may have the structure of FIGS. 7A to 7D.

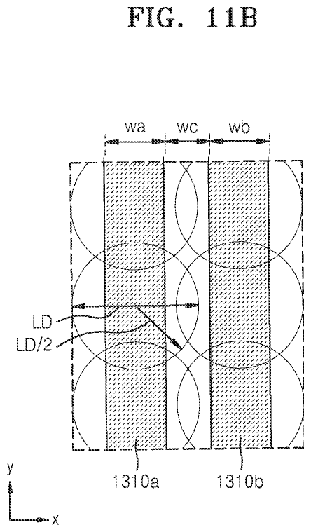

FIG. 11A is an enlarged cross-sectional view of a portion VIII of FIG. 10A, and FIG. 11B is a plan view of a portion VIII of FIG. 10A.

Referring to FIGS. 11A and 11B, the 1-1 line 1310a and the 1-2 line 1310b may be apart from each other. As described above, the laser may be irradiated in a direction from the lower surface of the substrate 100 to the upper surface thereof. In the laser lift-off process, the laser may be irradiated by moving laser beams having a uniform diameter. For example, as illustrated, the laser beams may be irradiated in the +x direction.

The width wa of the 1-1 line 1310a and the width wb of the 1-2 line 1310b may each be between about 1.8 μm and about 30 μm and may be the same as or different from each other. A diameter LD of the laser beam may be greater than the width wa of the 1-1 line 1310a and the width wb of the 1-2 line 1310b. A radius LD/2 of the laser beam may be less than half of a sum of the width wa of the 1-1 line 1310a and a gap wc between the 1-1 line 1310a and the 1-2 line 1310b. Likewise, the radius LD/2 of the laser beam may be less than half of a sum of the width wb of the 1-2 line 1310b and the gap wc between the 1-1 line 1310a and the 1-2 line 1310b. Therefore, a first beam Beam1 irradiated onto the 1-1 line 1310a may not overlap the 1-2 line 1310b, a second beam Beam2 irradiated onto the 1-2 line 1310b may not overlap the 1-1 line 1310a, and the first beam Beam1 and the second beam Beam2 may overlap in an area between the 1-1 line 1310a and the 1-2 line 1310b. An area, where the laser beams overlap and are irradiated, decreases on the sacrificial layer 1300 (see FIG. 10A), the damage to the substrate 100 may be reduced.

As the lines are arranged in slit forms in the first area PA1 (see FIG. 10A) between the end portions of the first organic insulating layer 211 and the second organic insulating layer 213 and the first partition PW1 and in the second area PA2 (see FIG. 10A) between the first partition PW1 and the second partition PW2, the laser lift-off may be performed without a residual metal layer with less laser outputs than when a single sacrificial layer is arranged in the same area.

According to the one or more embodiments, a display apparatus having an area, where various types of components may be arranged in a display area, and preventing the moisture penetration and the crack occurrence, and a method of manufacturing the display apparatus may be realized. However, the scope of the disclosure is not limited to the effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display apparatus comprising:
a substrate comprising an opening area, a display area surrounding at least a portion of the opening area, and an intermediate area between the opening area and the display area;
an organic insulating layer in the display area;
a display element on the organic insulating layer and comprising a pixel electrode, an opposite electrode on the pixel electrode, and an intermediate layer between the pixel electrode and the opposite electrode; and
a partition layer in the intermediate area and comprising a first partition and a second partition,
wherein the intermediate layer comprises an organic layer extending toward the intermediate area from the display area, and
the organic layer is separated by a plurality of first openings in an area between the organic insulating layer and the first partition and by a plurality of second openings in an area between the first partition and the second partition.

2. The display apparatus of claim 1, further comprising:
a thin film transistor in the display area and comprising a semiconductor layer and a gate electrode overlapping at least a portion of the semiconductor layer;
a first interlayer insulating layer on the thin film transistor; and
a second interlayer insulating layer on the first interlayer insulating layer,
wherein the second interlayer insulating layer further comprises a second inorganic layer extending toward the intermediate area from the display area, and
the second inorganic layer comprises a plurality of first through holes overlapping the plurality of first openings and the plurality of second openings.

3. The display apparatus of claim 2, wherein the first interlayer insulating layer comprises a first inorganic layer extending toward the intermediate area from the display area, and
the first inorganic layer comprises a plurality of second through holes overlapping the plurality of first openings and the plurality of second openings.

4. The display apparatus of claim 1, further comprising a stopper layer under the organic layer and in contact with the organic layer, and comprising a plurality of third through holes corresponding to the plurality of first openings and the plurality of second openings.

5. The display apparatus of claim 1, wherein the organic layer is separated by a plurality of third openings in an area between the second partition and the opening area, and
a width of each of the plurality of third openings is a same as a width of each of the plurality of first openings.

6. The display apparatus of claim 1, wherein the plurality of first openings comprise at least two openings having a closed-loop shape, the at least two openings having a same center and different diameters.

7. The display apparatus of claim 6, wherein the plurality of second openings comprise at least two openings having a closed-loop shape, the at least two openings having a same center and different diameters.

8. The display apparatus of claim 1, wherein the opposite electrode extends toward the intermediate area from the display area and comprises an electrode opening in the intermediate area, and
an edge portion of the opposite electrode, which defines an outline of the electrode opening, is in an area between the organic insulating layer and the first partition.

9. The display apparatus of claim 8, further comprising an encapsulation layer on the display element and comprising at least one inorganic encapsulation layer and an organic encapsulation layer,
wherein the edge portion of the opposite electrode overlaps the organic encapsulation layer.

10. A method of manufacturing a display apparatus, the method comprising:
preparing a substrate comprising an opening area, a display area surrounding at least a portion of the opening area, and an intermediate area between the opening area and the display area;
forming a pixel circuit in the display area;
forming a sacrificial layer in the intermediate area;
forming an organic insulating layer on an upper portion of the pixel circuit;
forming, in the intermediate area, a partition layer comprising a first partition and a second partition;
sequentially forming, on the organic insulating layer, a pixel electrode electrically connected to the pixel circuit, an intermediate layer, and an opposite electrode;
irradiating a laser onto an organic layer on which the intermediate layer extends from the display area toward the intermediate layer; and
forming, on the opposite electrode, an encapsulation layer comprising at least one inorganic encapsulation layer and an organic encapsulation layer,
wherein the forming of the sacrificial layer comprises forming a plurality of first lines in an area between the organic insulating layer and the first partition and forming a plurality of second lines in an area between the first partition and the second partition.

11. The method of claim 10, further comprising forming a stopper layer in the intermediate area before the forming of the organic insulating layer.

12. The method of claim 10, wherein the forming of the pixel circuit comprises:
forming at least one metal layer in the display area; and
forming at least one inorganic insulating layer on the at least one metal layer,
wherein the sacrificial layer comprises a same material as the at least one metal layer.

13. The method of claim 12, wherein the inorganic insulating layer further comprises an inorganic layer extending toward the intermediate area from the display area, and
the irradiating of the laser comprises removing together the organic layer and the inorganic layer, which are on the sacrificial layer, by removing the sacrificial layer through laser irradiation.

14. The method of claim 13, wherein, as the sacrificial layer, and the organic layer and the inorganic layer, which are on the sacrificial layer, are removed together, the organic layer is separated by a plurality of first openings in an area between the organic insulating layer and the first partition and by a plurality of second openings in an area between the first partition and the second partition.

15. The method of claim 12, wherein the forming of the sacrificial layer further comprises forming a plurality of third lines in an area between the second partition and the opening area.

16. The method of claim 15, wherein a width of each of the plurality of third lines is a same as a width of each of the plurality of first lines.

17. The method of claim 15, wherein the inorganic insulating layer further comprises an inorganic layer extending from the display area toward the intermediate area, and,
as the sacrificial layer, and the organic layer and the inorganic layer, which are on the sacrificial layer, are removed together, the organic layer is separated by a plurality of third openings in an area between the second partition and the opening area.

18. The method of claim 10, wherein, in the irradiating of the laser, an electrode opening is formed by removing a portion of the opposite electrode through laser irradiation.

19. The method of claim 18, wherein an edge portion of the opposite electrode, which defines an outline of the electrode opening, overlaps the organic encapsulation layer.

20. The method of claim 10, wherein a width of each of the plurality of first lines and the plurality of second lines is less than a diameter of a laser beam.
